(19) United States
(12) Patent Application Publication
(10) Pub. No.: US 2025/0300091 A1
(43) Pub. Date: Sep. 25, 2025

(54) SEMICONDUCTOR PACKAGES AND METHODS OF FORMATION

(71) Applicant: Taiwan Semiconductor Manufacturing Company, Ltd., Hsinchu (TW)

(72) Inventors: Chun-Hao LIN, Tainan City (TW); Yu-Jen WANG, Kaohsiung City (TW); Chun-Hao CHOU, Tainan City (TW)

(21) Appl. No.: 18/753,318

(22) Filed: Jun. 25, 2024

Related U.S. Application Data
(60) Provisional application No. 63/567,234, filed on Mar. 19, 2024.

(51) Int. Cl. H01L 23/00; H01L 21/768; H01L 23/48; H01L 23/522; H01L 23/58; H01L 25/00; H01L 25/065; H01L 27/146

(52) U.S. Cl. CPC H01L 23/562; H01L 21/76898; H01L 23/481; H01L 23/585; H01L 24/08; H01L 25/0657; H01L 25/50; H01L 23/5226; H01L 2224/08146; H10F 39/809

(57) ABSTRACT

A semiconductor package includes a first semiconductor die and a second semiconductor die bonded together such that the first semiconductor die and the second semiconductor die are stacked or vertically arranged in the semiconductor package. A seal ring region is provided around the device regions of the first semiconductor die and the second semiconductor die. To prevent, minimize, and/or reduce the likelihood of electrical leakage propagating between the first and second semiconductor dies through the seal ring region, one or more through-substrate isolation structures are included through a substrate of the first semiconductor die and/or through a substrate of the second semiconductor die in the seal ring region.

### CROSS-REFERENCE TO RELATED APPLICATION

This Patent application claims priority to U.S. Provisional Patent Application No. 63/567,234, filed on Mar. 19, 2024, and entitled “SEMICONDUCTOR PACKAGES AND METHODS OF FORMATION.” The disclosure of the prior Application is considered part of and is incorporated by reference into this Patent Application.

### BACKGROUND

Various semiconductor device packing techniques may be used to incorporate one or more semiconductor dies into a semiconductor package. In some cases, semiconductor dies may be horizontally interconnected through an interposer. Additionally and/or alternatively, semiconductor dies may be arranged vertically in a semiconductor package to achieve a smaller horizontal or lateral footprint of the semiconductor package and/or to increase the density of the semiconductor package. The semiconductor dies may be connected directly through die-to-die (or wafer-to-wafer) bonding and/or through interconnects and one or more interposers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of example semiconductor packages described herein.

FIGS. 2A-2J are diagrams of example implementations of seal ring regions described herein.

FIGS. 3A-3H are diagrams of an example implementation of forming a semiconductor die described herein.

FIGS. 4A and 4B are diagrams of an example implementation of forming a semiconductor package described herein.

FIGS. 5A-5E are diagrams of an example implementation of forming a through-substrate isolation structure in a seal ring region described herein.

FIG. 6 is a diagram of an example semiconductor package described herein.

FIGS. 7A-7K are diagrams of an example implementation of forming an interconnect layer of a semiconductor die described herein.

FIG. 8 is a diagram of an example semiconductor package described herein.

FIG. 9 is a diagram of an example semiconductor package described herein.

FIG. 10 is a diagram of an example semiconductor package described herein.

FIG. 11 is a diagram of an example semiconductor package described herein.

FIG. 12 is a flowchart of an example process associated with forming a semiconductor package described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor package may include a seal ring region around a device region of the semiconductor package. The seal ring region may include a ring of interconnected metallization layers that provide increased structural rigidity for the semiconductor package, which may reduce the likelihood of cracking, warpage, and/or another type of physical damage that might otherwise result from physical stresses that are exerted on the semiconductor package. Additionally and/or alternatively, the interconnected metallization layers in the seal ring region may be configured to provide a humidity seal for the semiconductor package, which may reduce the likelihood of humidity ingress in the semiconductor package. However, the interconnected metallization layers in the seal ring region may provide an unintended electrical leakage path between the semiconductor dies of the semiconductor package. This electrical leakage can result in operation of one semiconductor die interfering with the operation of another semiconductor die in the semiconductor package.

In some implementations described herein, a semiconductor package includes a first semiconductor die and a second semiconductor die bonded together such that the first semiconductor die and the second semiconductor die are stacked or vertically arranged in the semiconductor package. A seal ring region is provided around the device regions of the first semiconductor die and the second semiconductor die. To prevent, minimize, and/or reduce the likelihood of electrical leakage propagating between the first and second semiconductor dies through the seal ring region, one or more through-substrate isolation structures are included through a substrate of the first semiconductor die and/or through a substrate of the second semiconductor die in the seal ring region. The through-substrate isolation structure(s) may include through-silicon via(s) (TSV(s)), through-substrate trenches, and/or another type of isolation structure(s) that extend fully through the substrate of the first semiconductor die and/or through the substrate of the second semiconductor die.

The through-substrate isolation structure(s) effectively extends the interconnected metallization layers in the seal ring region through the substrate of the first semiconductor die and/or through the substrate of the second semiconductor die, to thereby prevent, minimize, and/or reduce the likelihood of electrical leakage being introduced into the device region of the first semiconductor die and/or into the device region of the second semiconductor die through the substrate of the first semiconductor die and/or through the substrate of the second semiconductor die.

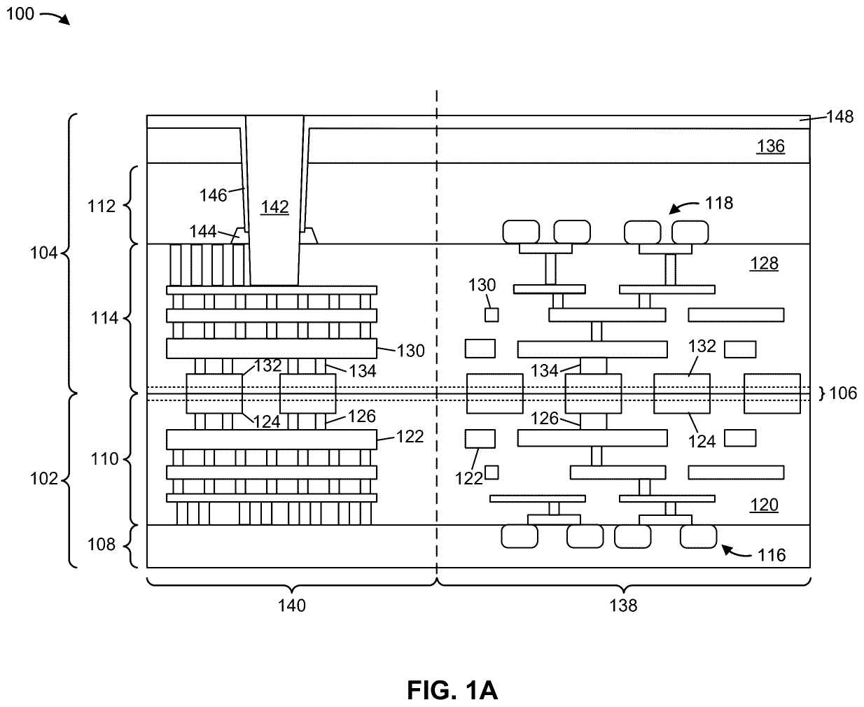

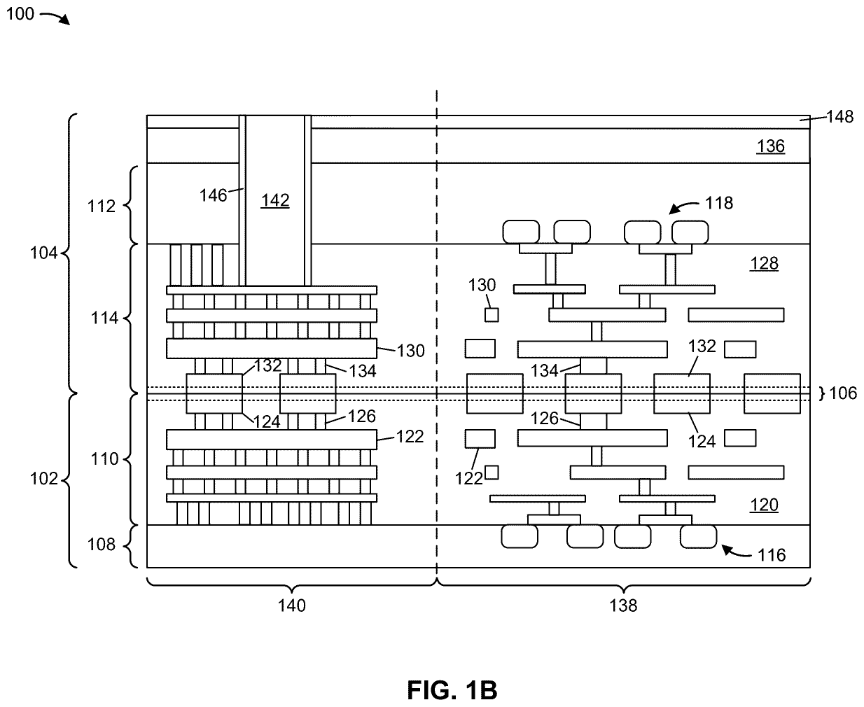

FIGS. 1A and 1B are diagrams of example semiconductor packages 100 described herein. FIGS. 1A and 1B each illustrate a cross-section view of an example semiconductor package 100. As shown in FIGS. 1A and 1B, the semiconductor package 100 includes a semiconductor die 102 and a semiconductor die 104 bonded at a bonding interface 106 such that the semiconductor dies 102 and 104 are stacked and vertically arranged in the semiconductor package 100. The bond between the semiconductor dies 102 and 104 may be formed by bonding semiconductor wafers together (e.g., wafer-to-wafer bonding), by bonding dies together (die-to-die bonding), and/or by bonding a die to a wafer (e.g., die-to-wafer bonding), among other example bonding configurations. A bonding tool may be used to perform a bonding operation to bond the semiconductor dies 102 and 104 by forming metal-to-metal bonds and/or dielectric-to-dielectric bonds at the bonding interface 106 between the semiconductor dies 102 and 104.

The semiconductor die 102 may include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the semiconductor die 102 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The semiconductor die 104 may include the same type of semiconductor die as the semiconductor die 102, or may include a different type of semiconductor die.

As further shown in FIGS. 1A and 1B, the semiconductor die 102 may include a semiconductor layer 108 and an interconnect layer 110 above the semiconductor layer 108. The semiconductor die 104 may include a semiconductor layer 112 and an interconnect layer 114 below the semiconductor layer 112. The bonding interface 106 may be located between the interconnect layers 110 and 114, and may include portions of each of the interconnect layers 110 and 114. The bonding interface 106 may include conductive structures of the interconnect layers 110 and 114 that are bonded together by metal-to-metal bonds, and/or dielectric layers of the interconnect layers 110 and 114 that are bonded together by dielectric-to-dielectric bonds.

The semiconductor layer 108 may correspond to a portion of a semiconductor wafer on which the semiconductor die 102 was formed, and the semiconductor layer 112 may correspond to a portion of another semiconductor wafer on which the semiconductor die 104 was formed. The semiconductor layer 108 and 112 may each include a silicon (Si) substrate, a substrate formed of a material including silicon, a III-V compound semiconductor material substrate such as gallium arsenide (GaAs), a silicon on insulator (SOI) substrate, or another type of semiconductor substrate.

The semiconductor layers 108 and 112 may respectively include integrated circuit devices 116 and 118 of the semiconductor dies 102 and 104. The integrated circuit devices 116 and 118 may each include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of passive and/or active integrated circuit devices.

The interconnect layers 110 and 114 may each include conductive structures that interconnect the integrated circuit devices 116 and 118 of the semiconductor layers 108 and 112, respectively. Additionally and/or alternatively, the interconnect layers 110 and 114 may each include conductive structures that electrically connect the semiconductor dies 102 and 104.

The interconnect layer 110 of the semiconductor die 102 includes one or more dielectric layers 120 that are arranged in a direction that is approximately perpendicular to the semiconductor layer 108. The dielectric layer(s) 120 may include backend dielectric layers (e.g., interlayer dielectric (ILD) layers, intermetal dielectric (IMD) layers) and etch stop layers (ESLs) that are arranged in an alternating manner in the interconnect layer 110. The dielectric layer(s) 120 may each include an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

The interconnect layer 110 includes a plurality of conductive structures 122 (e.g., electrically conductive structures) in the dielectric layer(s) 120. The conductive structures 122 are electrically coupled and/or physically coupled with one or more of the integrated circuit devices 116 in the semiconductor layer 108, and are electrically interconnected together in the interconnect layer 110. The conductive structures 122 correspond to circuit routing that enables signals and/or power to be provided to and/or from the integrated circuit devices 116. The conductive structures 122 may include a combination of conductive structures that extend primarily horizontally in the interconnect layer 110 (e.g., trenches, conductive lines) and that are interconnected by interconnect structures (e.g., vias) that extend primarily vertically in the interconnect layer 110. The conductive structures 122 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The conductive interconnects of the interconnect layer 110 may be arranged in a vertical manner to facilitate electrical signals and/or power to be routed between the semiconductor layer 108 and the semiconductor die 104, between integrated circuit devices 116 through the interconnect layer 110, and/or between the integrated circuit devices 116 and the integrated circuit devices 118 in the semiconductor die 104. The conductive structures 122 may be arranged in alternating layers of metallization layers (referred to as “M”-layers) and via layers (referred to as “V”-layers). Each metallization layer may include one or more conductive structures laterally arranged in the interconnect layer 110, and each via layer may include one or more interconnect structures that interconnect the metallization layers in the interconnect layer 110. As an example, a metal-0 (M0) layer may be located at the bottom of the interconnect layer 110 and may be coupled with the integrated circuit devices 116 in the semiconductor layer 108, a via-0 (V0) layer may be located above and coupled with the M0 layer in the interconnect layer 110, a metal-1 (M1) layer may be located above and coupled with the V0 layer in the interconnect layer 110, a via-1 (V1) layer may be located above and coupled with the M1 layer in the interconnect layer 110, a metal-2 (M2) layer may be located above and electrically coupled with the V1 layer in the interconnect layer 110, and so on. In some implementations, the interconnect layer 110 includes nine (9) stacked metallization layers (e.g., M0-M8). In other implementations, the contact layer (referred to as “CO”-layer) may be located at the bottom of the interconnect layer 110 and may be coupled with the integrated circuit devices 116 in the semiconductor layer 108, a metal-1 (M1) layer may be located above and coupled with the CO layer in the interconnect layer 110, and so on. In some implementations, the interconnect layer 110 includes another quantity of stacked metallization layers.

At the bonding interface 106, the interconnect layer 110 may include a plurality of bonding pads 124. The bonding pads 124 may be electrically coupled with the conductive structures 122 in the interconnect layer 110 by bonding vias 126 and/or other types of conductive structures. The bonding pads 124 and bonding vias 126 may each include tungsten (W), cobalt (Co), ruthenium (Ru), titanium (Ti), aluminum (Al), copper (Cu), gold (Au), and/or a combination thereof, among other examples of electrically conductive metals. In some implementations, one or more bonding pads 124 are each coupled to a single bonding via 126. In some implementations, one or more bonding pads 124 are each coupled to two or more bonding vias 126.

As further shown in FIGS. 1A and 1B, the interconnect layer 114 of the semiconductor die 104 may include a similar combination and/or arrangement of structures and/or layers as the interconnect layer 110 of the semiconductor die 102. For example, the semiconductor die 104 may include a combination of one or more dielectric layers 128 and conductive structures 130 in the dielectric layer(s) 128. Moreover, the interconnect layer 114 may include bonding pads 132 that are electrically coupled with one or more of the conductive structures 130 (e.g., by bonding vias and/or other types of conductive structures) through bonding vias 134. These layers and/or structures may have a reversed vertical arrangement relative to the semiconductor die 102, which enables the semiconductor die 102 and the semiconductor die 104 to be bonded at the bonding interface 106 such that the interconnect layer 110 and the interconnect layer 114 are facing each other.

At the bonding interface 106, the bonding pads 124 of the semiconductor die 102 and the bonding pads 132 of the semiconductor die 104 are directly bonded by metal-to-metal bonds. Moreover, a dielectric layer of the one or more dielectric layers 120 of the semiconductor die 102 and a dielectric layer of the one or more dielectric layers 128 of the semiconductor die 104 are directly bonded by dielectric-to-dielectric bonds.

The interconnect layer 114 may be included on a front side of the semiconductor layer 112. On the back side of the semiconductor layer 112 opposite the front side, a passivation layer 136 may be included to passivate the back side surface of the semiconductor layer 112. The passivation layer 136 may include one or more dielectric materials such as an oxide (e.g., a silicon oxide (SiOₓ) and/or another oxide material), a USG, a BSG, an FSG, an ELK dielectric material, a silicon nitride (SiₓN_{y}), silicon carbide (SiC), silicon oxynitride (SiON), and/or another suitable dielectric material including one or more high dielectric constant (high-k) dielectrics.

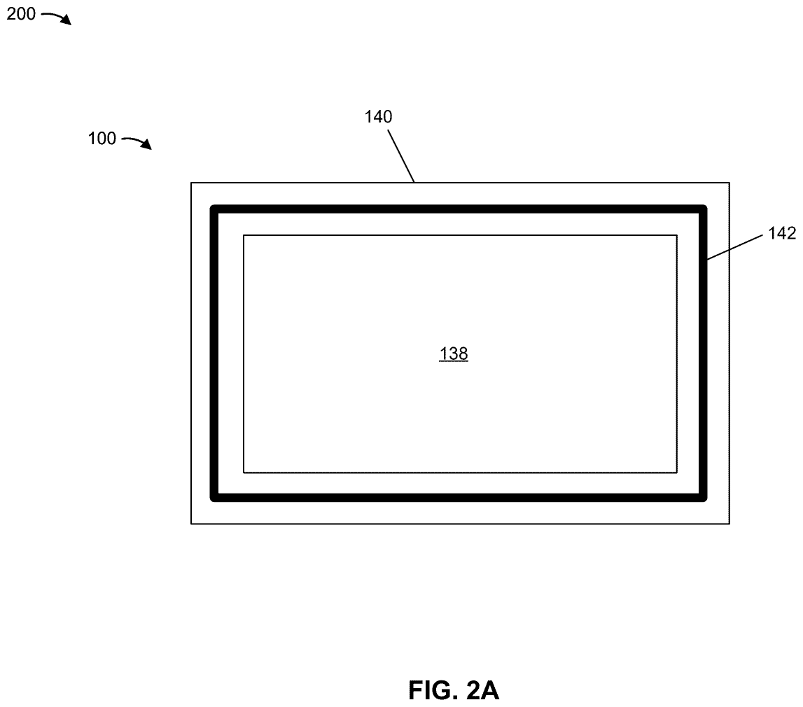

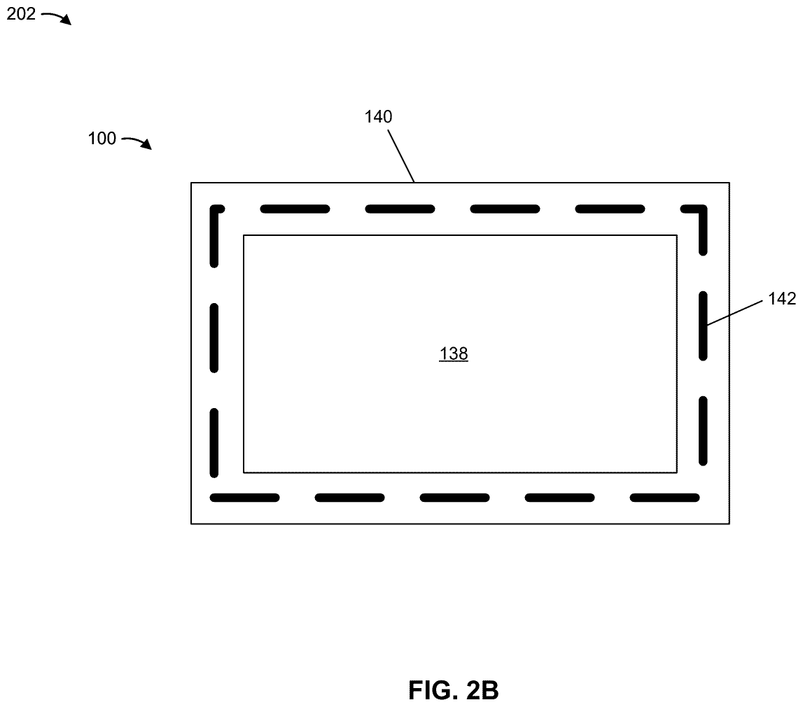

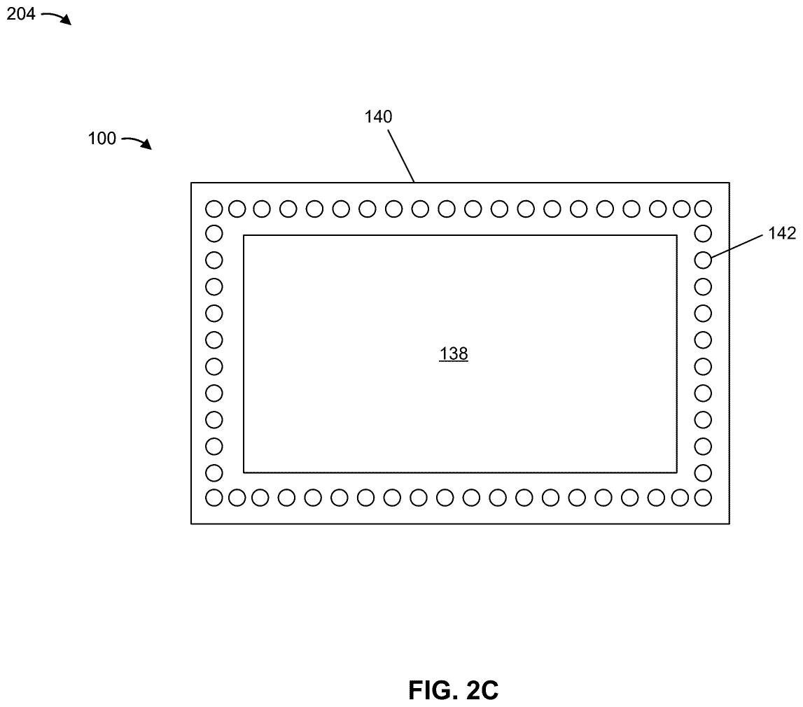

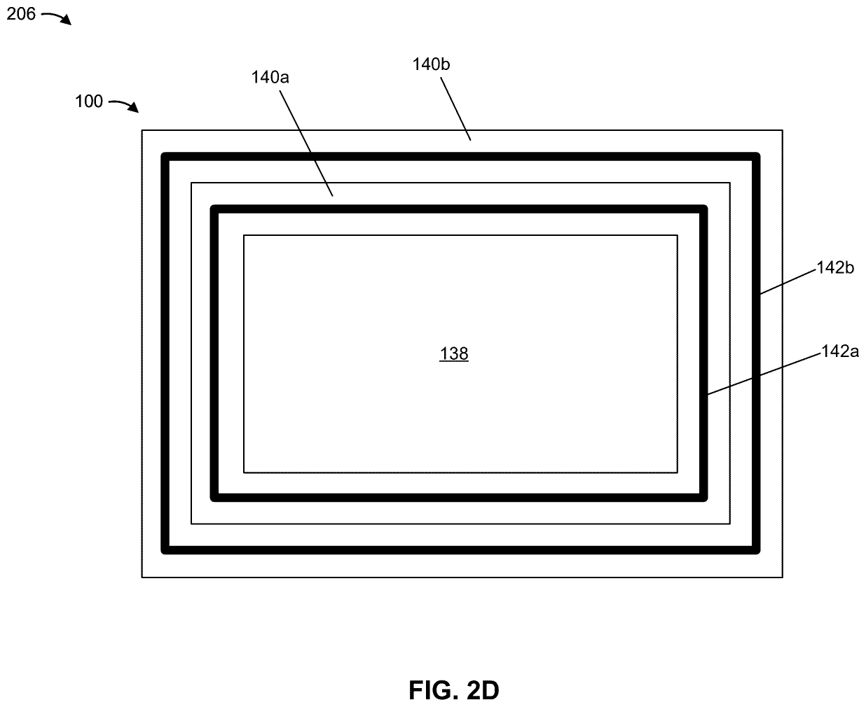

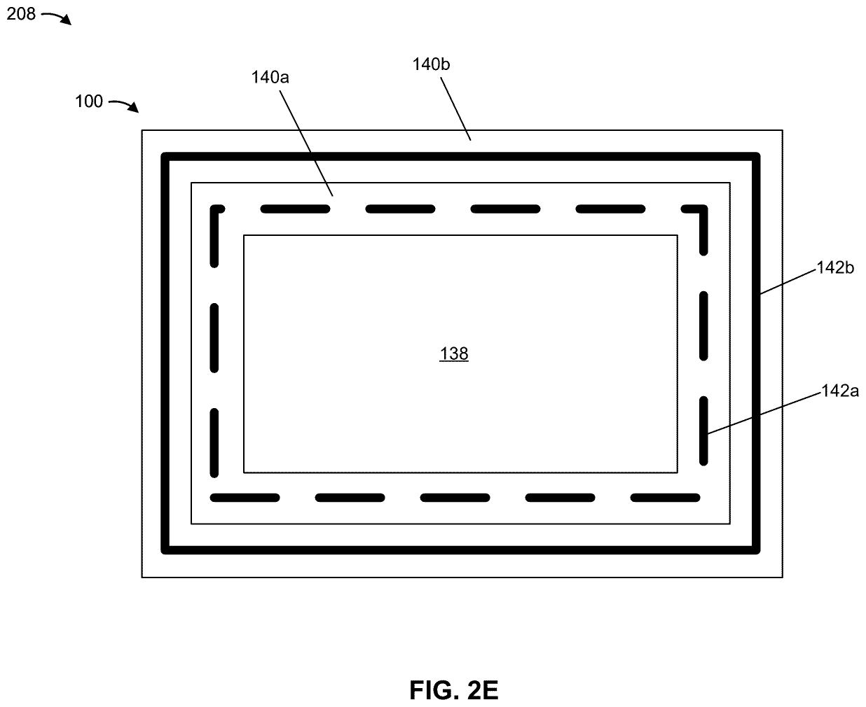

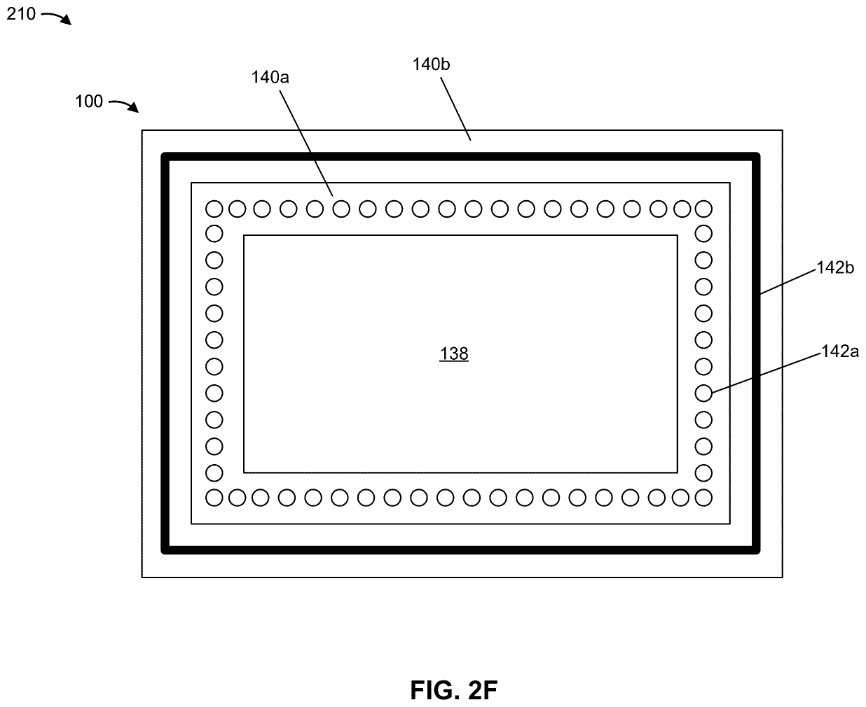

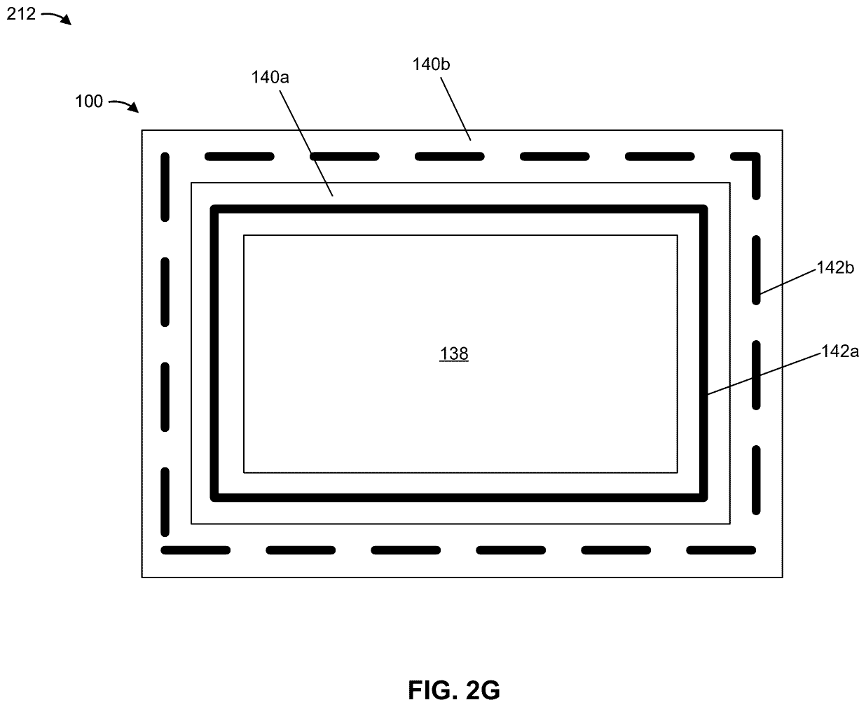

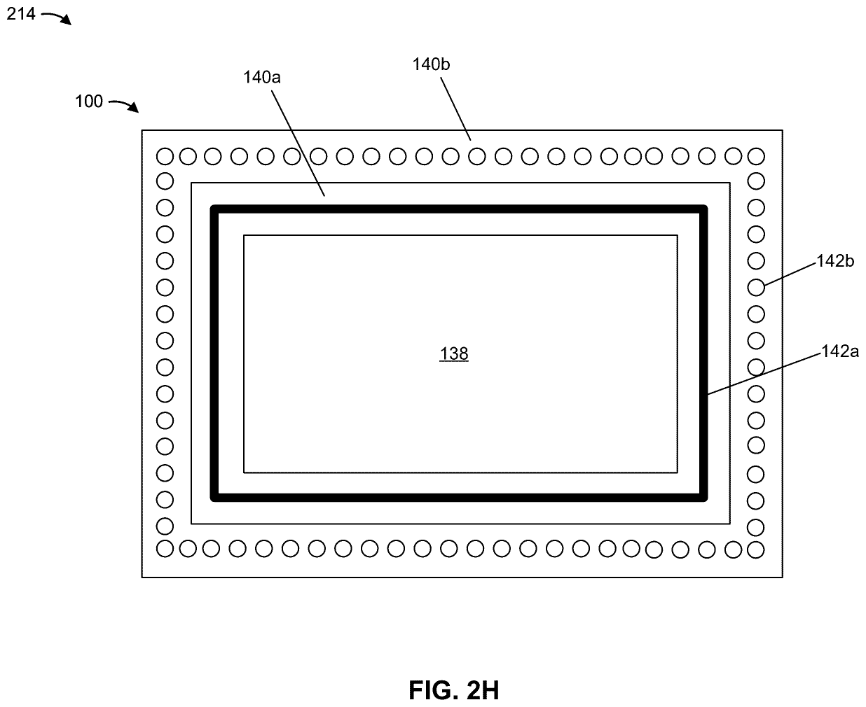

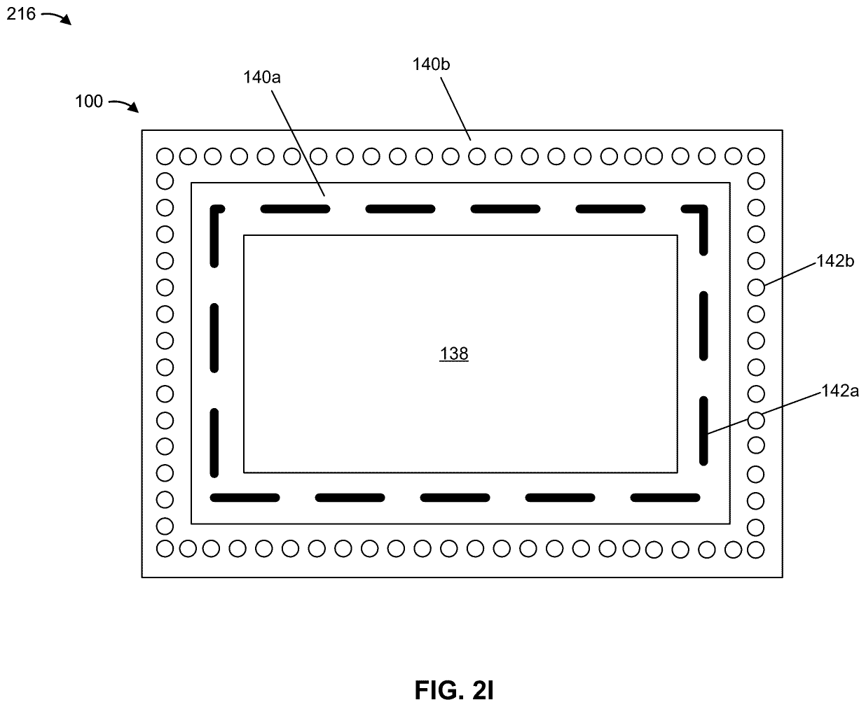

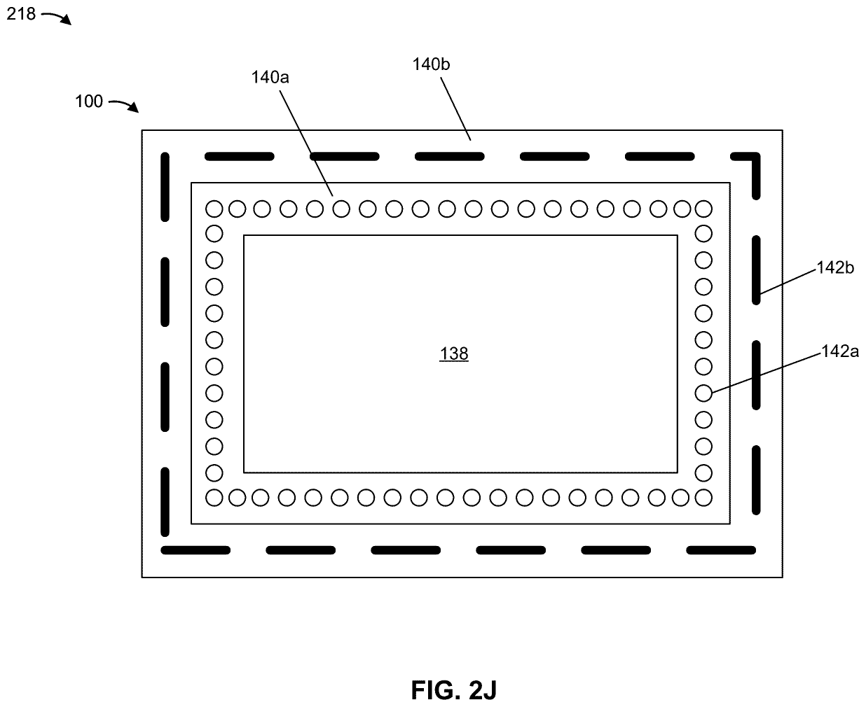

As further shown in FIGS. 1A and 1B, the semiconductor package 100 includes a plurality of topographical (or layout) regions that include structures configured to perform different functions. These topographical regions are further illustrated in top views in FIGS. 2A-2J. The semiconductor package 100 includes a device region 138 that includes the integrated circuit devices 116 and the integrated circuit devices 118. In other words, the device region 138 may be configured to perform the main functions of the semiconductor package 100, which may include processing, memory, input/output (I/O), and/or power delivery, among other examples.

A seal ring region 140 laterally surrounds the device region 138 (which is shown in various top views in FIGS. 2A-2J). The seal ring region 140 is included to provide increased structural rigidity for the semiconductor package, which may reduce the likelihood of cracking, warpage, and/or another type of physical damage that might otherwise result from physical stresses that are exerted on the semiconductor package. The seal ring region 140 may also be included to provide a humidity seal for the device region 138 of the semiconductor package 100, which may reduce the likelihood of humidity ingress into the device region 138 of the semiconductor package 100. The seal ring region 140 may also be included to provide electrical isolation (e.g., shielding) for the device region 138 from external electrical effects such as radio frequency (RF) interference, electromagnetic interference (EMI), and/or current leakage, among other examples.

The seal ring region 140 includes an arrangement of conductive structures 122, bonding pads 124, and bonding vias 126 in the semiconductor die 102, and an arrangement of conductive structures 130, bonding pads 132, and bonding vias 134 in the semiconductor die 104. These structures are arranged in a manner such that the conductive structures 122, the bonding pads 124, the bonding vias 126, the conductive structures 130, the bonding pads 132, and the bonding vias 134 provide a metal seal around the device region 138.

The seal ring region 140 further includes a through-substrate isolation structure 142 that extends through the semiconductor layer 112 of the semiconductor die 104. The seal ring region 140 extends into the dielectric layer 128 of the interconnect layer 114 on the front side of the semiconductor layer 112 at a first end of the through-substrate isolation structure 142, and into the passivation layer 136 on the back side of the semiconductor layer 112 at a second end of the through-substrate isolation structure 142 opposing the first end. The through-substrate isolation structure 142 is physically coupled with a conductive structure 130 in the interconnect layer 114. In this way, the through-substrate isolation structure 142 extends the hermetic seal and electrical isolation of the seal ring region 140 into the semiconductor layer 112 of the semiconductor die 104.

In particular, the through-substrate isolation structure 142 blocks or inhibits electrical effects (e.g., RF interference, EMI, current leakage) from propagating into and/or out of the portion of the semiconductor layer 112 in the device region 138 through the conductive structures 122 and/or 130, through the bonding vias 126 and/or 134, and/or through the bonding pads 124 and/or 132. In this way, the through-substrate isolation structure 142 protects the integrated circuit devices 118 in the device region 138 from being affected by external electrical effects and/or electrical effects from the semiconductor die 102, and/or protects the integrated circuit devices 116 in the device region 138 from being affected by external electrical effects and/or electrical effects from the semiconductor die 104.

Moreover, the through-substrate isolation structure 142 blocks or inhibits ingress of humidity, vibration, and/or other contaminants from propagating through the semiconductor layer 112 and into the device region 138, thereby protecting the integrated circuit devices 118 in the device region 138 from being exposed to such humidity, vibration, and/or other contaminants.

The through-substrate isolation structure 142 may include a TSV, a metal pillar, a metal column, a through-substrate trench, and/or another type of electrically conductive structure that extends through the semiconductor layer 112. FIG. 1A illustrates an example implementation in which the through-substrate isolation structure 142 has tapered sidewalls and is formed by a TSV process. FIG. 1B illustrates an example implementation in which the through-substrate isolation structure 142 has approximately vertical sidewalls and is formed by a backside passivation (BPASS) process. Alternatively, the through-substrate isolation structure 142 may have angled or tapered sidewalls, similar to the example in FIG. 1A. In FIG. 1A, the through-substrate isolation structure 142 extends through a shallow trench isolation (STI) region 144 that is included in the semiconductor layer 112. The STI region 144 may include one or more dielectric materials such as a silicon oxide material (SiOₓ such as SiO₂), a silicon nitride material (SiₓN_{y} such Si₃N₄), and/or another suitable dielectric material. In FIG. 1B, the STI region 144 is omitted. Alternatively, the STI region 144 may be included in the example in FIG. 1B.

The through-substrate isolation structure 142 may include one or more electrically conductive materials, such as copper (Cu), gold (Au), silver (Ag), nickel (Ni), tin (Sn), ruthenium (Ru), cobalt (Co), tungsten (W), titanium (Ti), aluminum copper (AlCu), one or more metals, one or more conductive ceramics, alloys thereof, and/or another type of electrically conductive material.

The through-substrate isolation structure 142 may include a metal material that is susceptible to diffusion into the semiconductor layer 112. Accordingly, one or more liners 146 may be included between the through-substrate isolation structure 142 and the semiconductor layer 112 to provide a diffusion barrier and/or to promote adhesion between the through-substrate isolation structure 142 and the semiconductor layer 112, among other examples. Moreover, in some implementations, an additional barrier layer is deposited on the one or more liners 146 to further suppress metal diffusion from the through-substrate isolation structure 142 more effectively. The one or more liners 146 may include a high-k dielectric liner, a low-k dielectric liner, and/or another type of liner. In some implementations, a plurality of liners 146 are included between the through-substrate isolation structure 142 and the semiconductor layer 112. The barrier layer, if included, may include diffusion blocking materials such as tantalum (Ta) and/or tantalum nitride (TaN), among other examples.

A high-k dielectric liner may include one or more high-k dielectric materials, such as silicon nitride (SiₓN_{y} such as Si₃N₄), an aluminum oxide (AlₓO_{y} such as Al₂O₃), a tantalum oxide (TaₓO_{y} such as Ta₂O₅), a titanium oxide (TiOₓ such as TiO₂), a zirconium oxide (ZrOₓ such as ZrO₂), a hafnium oxide (HfOₓ such as HfO₂), a strontium titanium oxide (SrTiOₓ such as SrTiO₃), hafnium silicon oxide (HfSiOₓ such as HfSiO₄), lanthanum oxide (LaₓO_{y} such as La₂O₃), yttrium oxide (YₓO_{y} such as Y₂O₃), and/or amorphous lanthanum aluminum oxide (a-LaAlOₓ such as a-LaAlO₃), among other examples. A low-k dielectric liner may include one or more low-k dielectric materials, such as a silicon oxide (SiOₓ), an undoped silicate glass (USG), a boron-containing silicate glass (BSG), and/or a fluorine-containing silicate glass (FSG), among other examples.

One or more buffer layers 148 may be included on the back side of the semiconductor layer 112. The buffer layer(s) 148 may be used to pattern the semiconductor layer 112 for formation of the through-substrate isolation structure 142. Additionally, the buffer layer(s) 148 may be included to protect the passivation layer 136 during a self-aligned etch for forming the recess for the through-substrate isolation structure 142, and during a planarization to planarize the through-substrate isolation structure 142, among other examples. The buffer layer(s) 148 may include one or more dielectric materials such as a silicon oxide material (SiOₓ such as SiO₂), a silicon nitride material (SiₓN_{y} such as Si₃N₄), and/or another suitable dielectric material.

As indicated above, FIGS. 1A and 1B are provided as examples. Other examples may differ from what is described with regard to FIGS. 1A and 1B.

FIGS. 2A-2J are diagrams of example implementations of seal ring regions 140 described herein. The example implementations of seal ring regions 140 illustrated in FIGS. 2A-2J may be implemented in one or more example implementations of semiconductor packages 100 described herein, such as those illustrated in FIGS. 1A, 1B, 6, 8, 9, and/or 10, among other examples.

As shown in an example implementation 200 in FIG. 2A, a seal ring region 140 of a semiconductor package 100 may be included around a device region 138 of the semiconductor package 100 such that the seal ring region 140 laterally surrounds the device region 138. The seal ring region 140 includes a through-substrate isolation structure 142 that is also included around the device region 138. In the example implementation 200, the through-substrate isolation structure 142 includes a continuous closed-loop trench that fully encircles the device region 138 in the top view of the semiconductor package 100. In some implementations, a top view width of the continuous closed-loop trench is included in a range of approximately 0.7 microns to approximately 3.2 microns. However, other values and ranges for the top view width of the continuous closed-loop trench are within the scope of the present disclosure.

As shown in an example implementation 202 in FIG. 2B, a seal ring region 140 of a semiconductor package 100 may be included around a device region 138 of the semiconductor package 100. The seal ring region 140 includes a cut through-substrate isolation structure 142 around the device region 138, where the cut through-substrate isolation structure 142 includes a plurality of non-contiguous through-substrate isolation trenches (e.g., trench segments) around the device region 138 in the top view of the semiconductor package 100.

As shown in an example implementation 204 in FIG. 2C, a seal ring region 140 of a semiconductor package 100 may be included around a device region 138 of the semiconductor package 100. The seal ring region 140 includes a plurality of through-substrate isolation structures 142 around the device region 138, where the through-substrate isolation structures 142 include a plurality of non-contiguous TSVs around the device region 138 in the top view of the semiconductor package 100.

As shown in an example implementation 206 in FIG. 2D, a semiconductor package 100 may include a plurality of seal ring regions around a device region 138 of the semiconductor package 100. The plurality of seal ring regions may include an inner seal ring region 140a around the device region 138 and an outer seal ring region 140b around the inner seal ring region 140a. In other implementations, a greater quantity of seal ring regions may be included around a device region 138 of a semiconductor package 100. Including a plurality of seal ring regions around a device region 138 may provide increased electrical isolation for the device region 138, increased humidity protection, and/or increased structural rigidity, among other examples.

The inner seal ring region 140a includes a through-substrate isolation structure 142a that is included around the device region 138. In the example implementation 206, the through-substrate isolation structure 142a includes a continuous closed-loop trench that fully encircles the device region 138 in the top view of the semiconductor package 100. The outer seal ring region 140b includes a through-substrate isolation structure 142b that is included around the through-substrate isolation structure 142a. In the example implementation 206, the through-substrate isolation structure 142b includes a continuous closed-loop trench that fully encircles the device region 138 in the top view of the semiconductor package 100.

As shown in an example implementation 208 in FIG. 2E, a semiconductor package 100 may include a plurality of seal ring regions around a device region 138 of the semiconductor package 100, including an inner seal ring region 140a around the device region 138 and an outer seal ring region 140b around the inner seal ring region 140a. The inner seal ring region 140a includes a through-substrate isolation structure 142a that is implemented as a plurality of non-contiguous through-substrate isolation trenches (e.g., trench segments) around the device region 138 in the top view of the semiconductor package 100. The outer seal ring region 140b includes a through-substrate isolation structure 142b that is implemented as a continuous closed-loop trench around the through-substrate isolation structures 142a.

As shown in an example implementation 210 in FIG. 2F, a semiconductor package 100 may include a plurality of seal ring regions around a device region 138 of the semiconductor package 100, including an inner seal ring region 140a around the device region 138 and an outer seal ring region 140b around the inner seal ring region 140a. The inner seal ring region 140a includes a plurality of through-substrate isolation structures 142a that are implemented as non-contiguous TSVs arranged around the device region 138 in the top view of the semiconductor package 100. The outer seal ring region 140b includes a through-substrate isolation structure 142b that is implemented as a continuous closed-loop trench around the through-substrate isolation structures 142a.

As shown in an example implementation 212 in FIG. 2G, a semiconductor package 100 may include a plurality of seal ring regions around a device region 138 of the semiconductor package 100, including an inner seal ring region 140a around the device region 138 and an outer seal ring region 140b around the inner seal ring region 140a. The inner seal ring region 140a includes a through-substrate isolation structure 142a that is implemented as a continuous closed-loop trench around the device region 138 in the top view of the semiconductor package 100. The outer seal ring region 140b includes a through-substrate isolation structure 142b that is implemented as a plurality of non-contiguous through-substrate isolation trenches (e.g., trench segments) arranged around the through-substrate isolation structure 142a.

As shown in an example implementation 214 in FIG. 2H, a semiconductor package 100 may include a plurality of seal ring regions around a device region 138 of the semiconductor package 100, including an inner seal ring region 140a around the device region 138 and an outer seal ring region 140b around the inner seal ring region 140a. The inner seal ring region 140a includes a through-substrate isolation structure 142a that is implemented as a continuous closed-loop trench around the device region 138 in the top view of the semiconductor package 100. The outer seal ring region 140b includes a plurality of through-substrate isolation structures 142b that are implemented as non-contiguous TSVs arranged around the through-substrate isolation structure 142a.

As shown in an example implementation 216 in FIG. 2I, a semiconductor package 100 may include a plurality of seal ring regions around a device region 138 of the semiconductor package 100, including an inner seal ring region 140a around the device region 138 and an outer seal ring region 140b around the inner seal ring region 140a. The inner seal ring region 140a includes a through-substrate isolation structure 142a that is implemented as a plurality of non-contiguous through-substrate isolation trenches (e.g., trench segments) around the device region 138 in the top view of the semiconductor package 100. The outer seal ring region 140b includes a plurality of through-substrate isolation structures 142b that are implemented as non-contiguous TSVs arranged around the through-substrate isolation structure 142a.

As shown in an example implementation 218 in FIG. 2J, a semiconductor package 100 may include a plurality of seal ring regions around a device region 138 of the semiconductor package 100, including an inner seal ring region 140a around the device region 138 and an outer seal ring region 140b around the inner seal ring region 140a. The inner seal ring region 140a includes a plurality of through-substrate isolation structures 142a that are implemented as non-contiguous TSVs arranged around the device region 138 in the top view of the semiconductor package 100. The outer seal ring region 140b includes a through-substrate isolation structure 142b that is implemented as a plurality of non-contiguous through-substrate isolation trenches (e.g., trench segments) around the through-substrate isolation structures 142a.

As indicated above, FIGS. 2A-2J are provided as examples. Other examples may differ from what is described with regard to FIGS. 2A-2J.

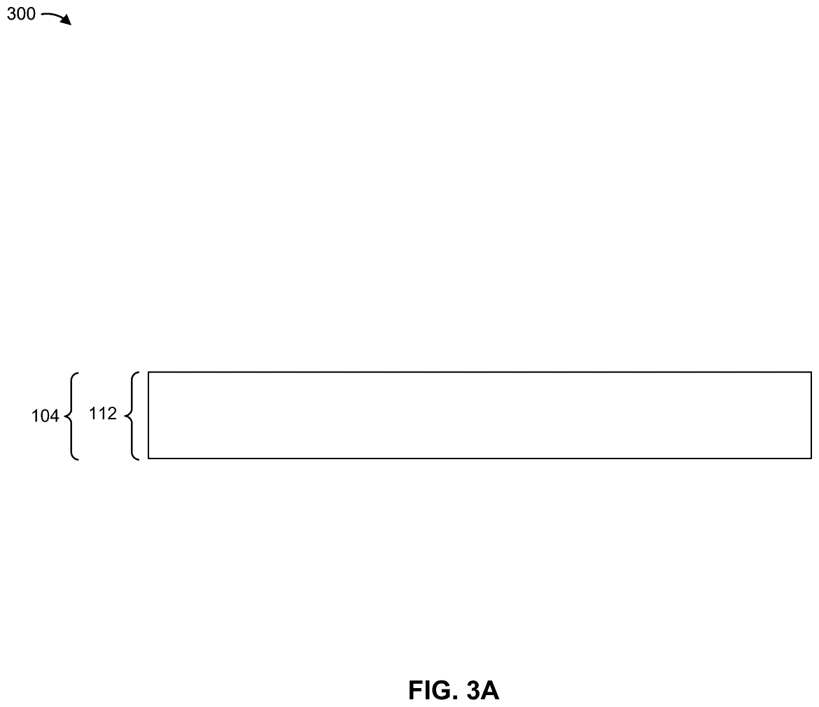

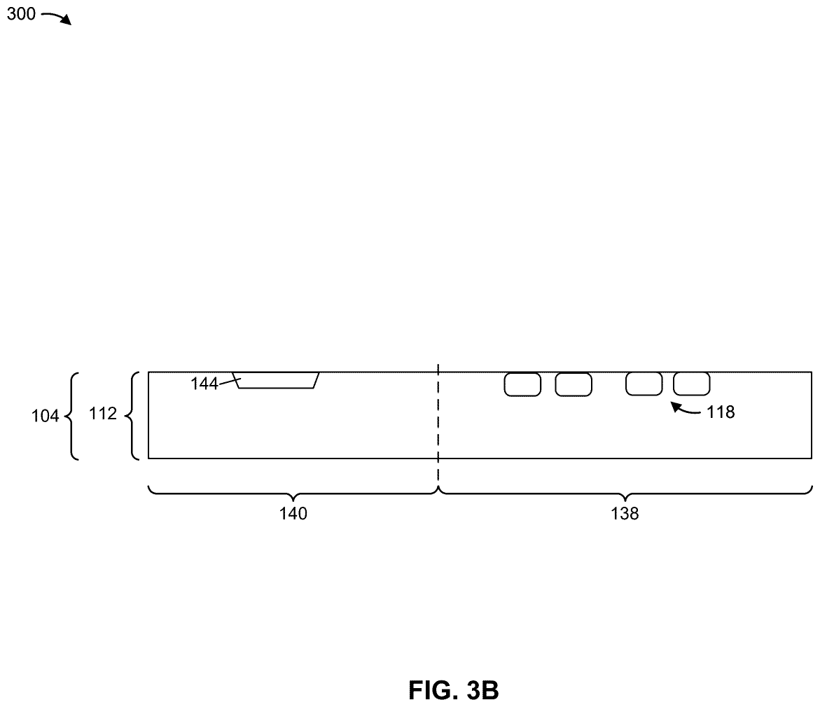

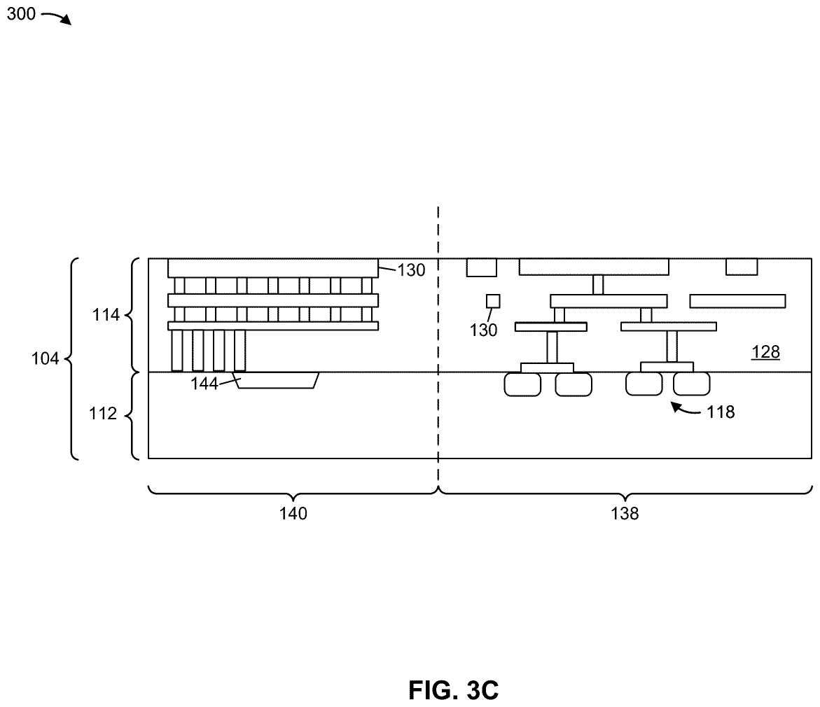

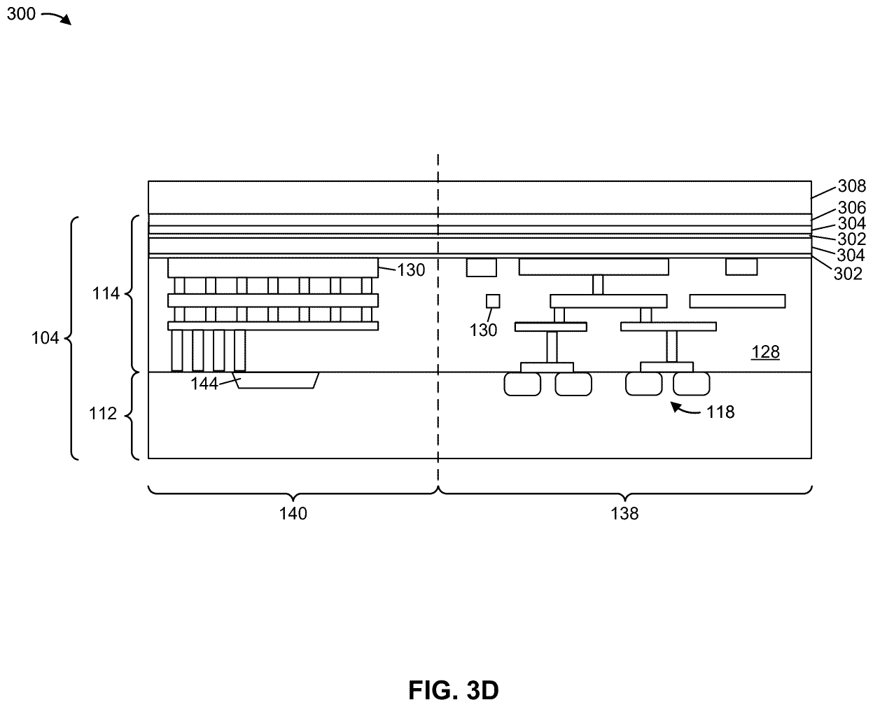

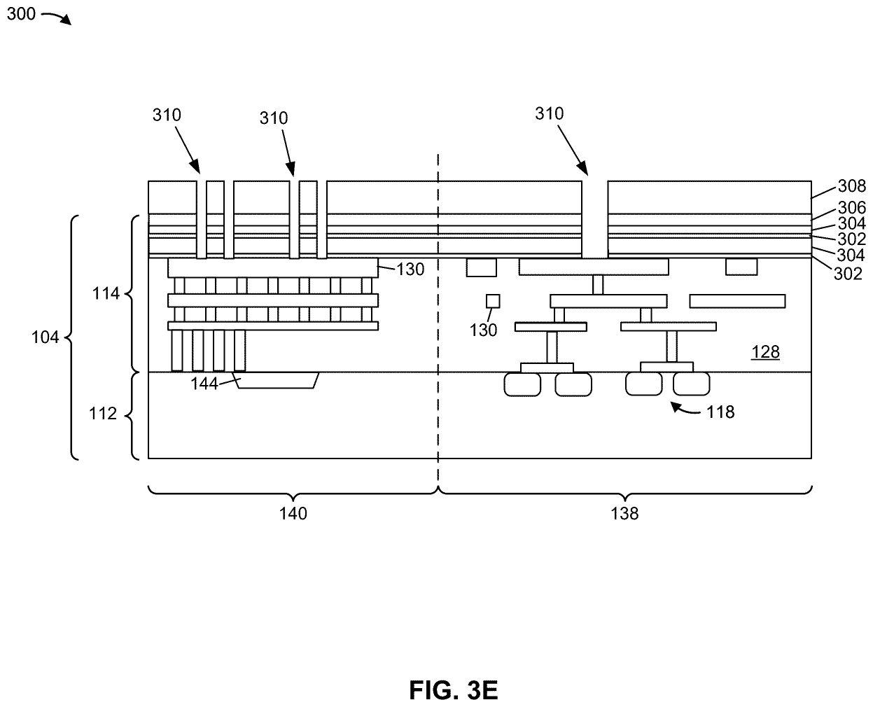

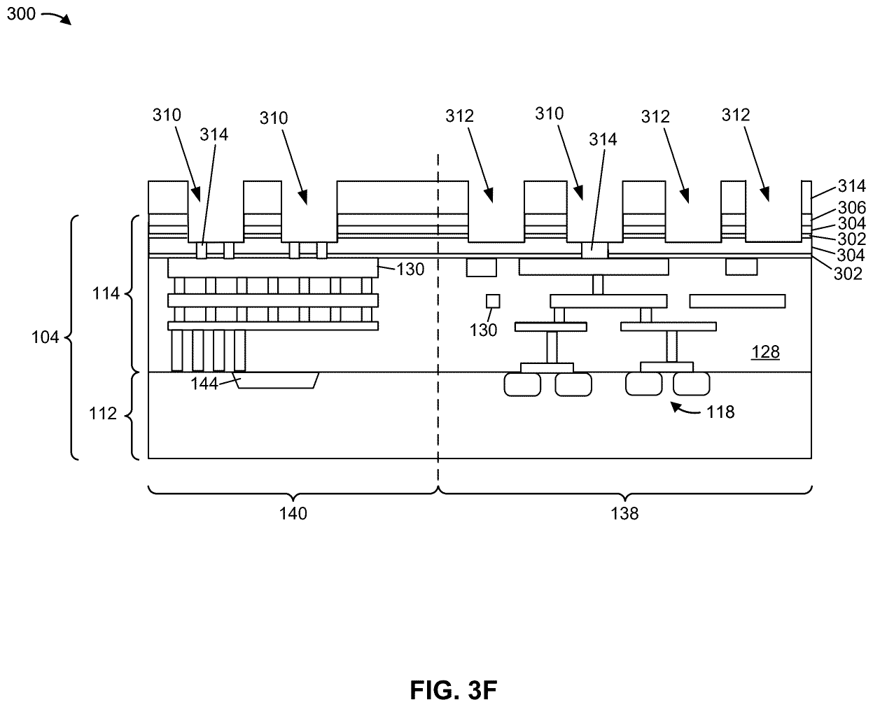

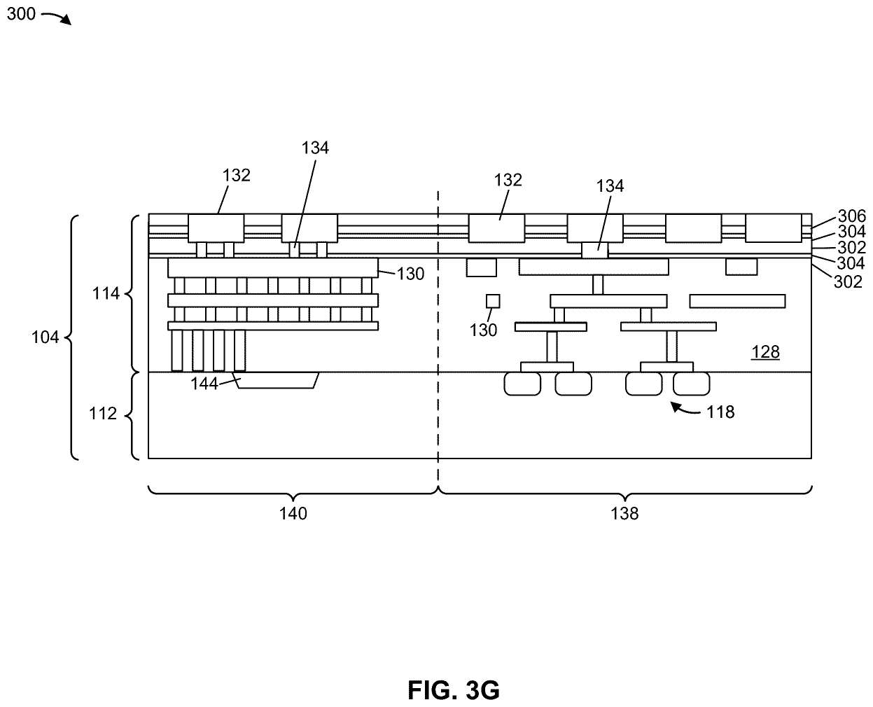

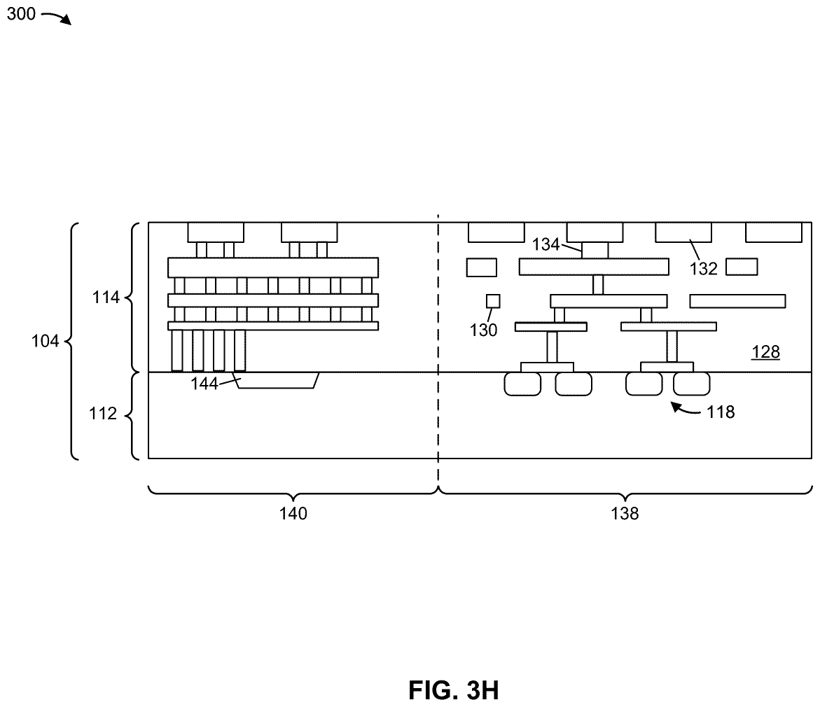

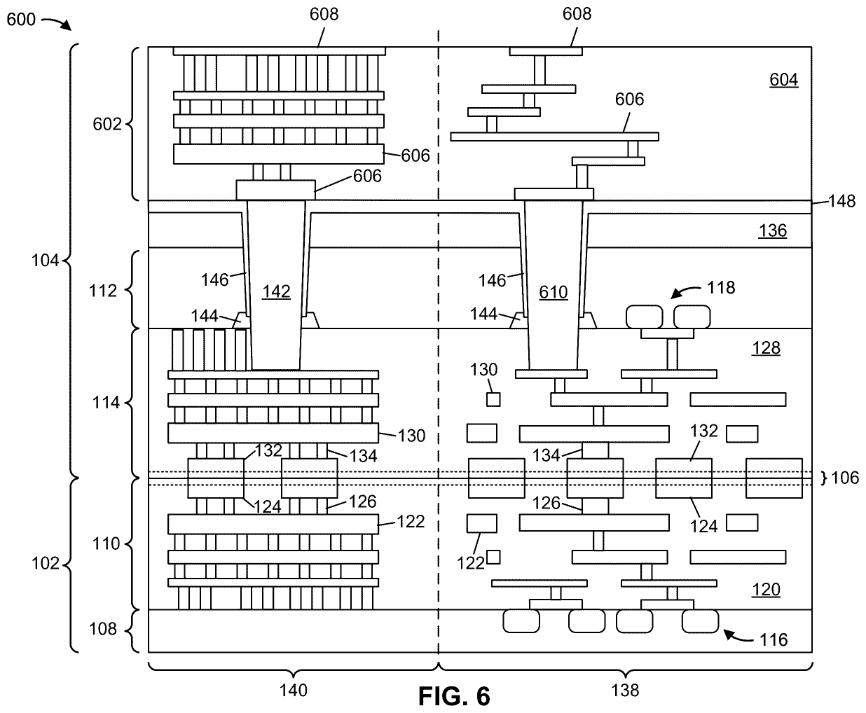

FIGS. 3A-3H are diagrams of an example implementation 300 of forming a semiconductor die described herein. In some implementations, the example implementation 300 includes an example process for forming a semiconductor die 104 or a portion thereof. In some implementations, one or more of the operations described in connection with the example implementation 300 may be performed to form another semiconductor die described herein, such as a semiconductor die 102, a semiconductor die 802 illustrated in FIGS. 6, 8-10, and/or another semiconductor die described herein. In some implementations, one or more semiconductor processing tools may be used to perform one or more of the operations described in connection with the example implementation 300, such as a deposition tool, an exposure tool, a developer tool, an etch tool, a planarization tool, a plating tool, and/or another type of semiconductor processing tool.

Turning to FIG. 3A, one or more of the operations in the example implementation 300 may be performed in connection with the semiconductor layer 112 of the semiconductor die 104. The semiconductor layer 112 may be provided in the form of a semiconductor wafer or another type of semiconductor substrate.

As shown in FIG. 3B, the integrated circuit devices 118 may be formed in and/or on the semiconductor layer 112 of the semiconductor die 104. In particular, the integrated circuit devices 118 may be formed in the device region of the semiconductor layer 112. One or more semiconductor processing tools may be used to form one or more portions of the integrated circuit devices 118. For example, a deposition tool may be used to perform various deposition operations to deposit layers of the integrated circuit devices 118, and/or to deposit photoresist layers for etching the semiconductor layer 112 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the semiconductor layer and/or portions of the deposited layers to form the integrated circuit devices 118. As another example, a planarization tool may be used to planarize portions of the integrated circuit devices 118. As another example, an ion implantation tool may be used to implant ions in the semiconductor layer to dope portions of the semiconductor layer 112 with one or more types of dopants (e.g., p-type dopants, n-type dopants).

As further shown in FIG. 3B, an STI region 144 may be formed in the semiconductor layer 112. The STI region 144 may be formed in a recess in the semiconductor layer 112. In particular, the STI region 144 may be formed in a portion of the semiconductor layer 112 in the seal ring region 140 of the semiconductor die 104. In some implementations, the STI region 144 is omitted.

In some implementations, a pattern in a photoresist layer is used to etch the semiconductor layer 112 to form the recess in the semiconductor layer 112. In these implementations, a deposition tool may be used to form the photoresist layer on the semiconductor layer 112. An exposure tool may be used to expose the photoresist layer to a radiation source to pattern the photoresist layer. A developer tool may be used to develop and remove portions of the photoresist layer to expose the pattern. An etch tool may be used to etch the semiconductor layer 112 based on the pattern to form the recess. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the semiconductor layer 112 based on a pattern.

A deposition tool may be used to deposit the dielectric material of the STI region 144 in the recess using a chemical vapor deposition (CVD) technique, an atomic layer deposition (ALD) technique, a physical vapor deposition (PVD) technique, an oxidation technique, and/or another suitable deposition technique. The dielectric material of the STI region 144 may be deposited in one or more deposition operations. In some implementations, a planarization tool may be used to perform a planarization operation (e.g., a chemical mechanical planarization (CMP) operation) to planarize the STI region 144 after the dielectric material of the STI region 144 is deposited.

As shown in FIG. 3C, the interconnect layer 114 of the second semiconductor die 104 may be formed over and/or on the semiconductor layer 112. One or more semiconductor processing tools may be used to form the interconnect layer 114 by forming one or more dielectric layers 128 and forming a plurality of conductive structures 130 in the dielectric layer(s) 128. For example, a deposition tool may be used to deposit a first layer of the dielectric layer(s) 128 (e.g., using a CVD technique, an ALD technique, a PVD technique, an oxidation technique, and/or another type of deposition technique), an etch tool may be used to remove portions of the first layer to form recesses in the first layer, and a deposition tool may be used to form a first layer (e.g., a via layer, a metallization layer) of one or more conductive structures 130 in the recesses (e.g., using a CVD technique, an ALD technique, a PVD technique, an electroplating technique, and/or another type of deposition technique). Similar processing operations may be performed to form additional layers of the interconnect layer 114 until a sufficient or desired arrangement of conductive structures 130 is achieved.

As shown in FIG. 3C, at least a portion of the conductive structures 130 in the device region 138 may be electrically connected and/or physically connected with the integrated circuit devices 118 in the semiconductor layer 112 (e.g., directly connected or connected through contacts). In the seal ring region 140, conductive structures 130 are arranged in a plurality of interconnected layers to provide a barrier around the device region 138.

As shown in FIG. 3D, additional dielectric layers of the interconnect layer 114 may be formed, including an alternating arrangement of nitride dielectric layers 302 and oxide dielectric layers 304. A bonding dielectric layer 306 may be formed on the alternating arrangement of nitride dielectric layers 302 and oxide dielectric layers 304. The nitride dielectric layers 302 may include a silicon nitride material (SiₓN_{y} such as Si₃N₄) and/or another suitable nitride-containing dielectric material. The oxide dielectric layers 304 may include a silicon oxide material (SiOₓ such as SiO₂) and/or another suitable oxide-containing dielectric material. The bonding dielectric layer 306 may include a silicon oxynitride material (SiON) and/or another suitable bonding dielectric material. A deposition tool may be used to deposit the nitride dielectric layers 302, the oxide dielectric layers 304, and the bonding dielectric layer 306, each using a CVD technique, an ALD technique, a PVD technique, an oxidation technique, and/or another suitable deposition technique. In some implementations, a planarization tool may be used to perform a planarization operation (e.g., a CMP operation) to planarize the nitride dielectric layers 302, the oxide dielectric layers 304, and/or the bonding dielectric layer 306.

As further shown in FIG. 3D, a photoresist layer 308 may be formed over the bonding dielectric layer 306. The photoresist layer 308 may be formed using a deposition tool by spin-coating and/or another suitable photoresist coating technique.

As shown in FIG. 3E, via portions of recesses 310 are formed through the nitride dielectric layers 302, the oxide dielectric layers 304, and the bonding dielectric layer 306. One or more of the conductive structures 130 in the interconnect layer 114 may be exposed through the recesses 310. In particular, one or more recesses 310 may be formed in the device region 138 such that one or more conductive structures 130 are exposed through the one or more recesses 310 in the device region 138, and one or more recesses 310 may be formed in the seal ring region 140 such that one or more conductive structures 130 are exposed through the one or more recesses 310 in the seal ring region 140.

In some implementations, a pattern in the photoresist layer 308 is used to etch the nitride dielectric layers 302, the oxide dielectric layers 304, and the bonding dielectric layer 306 to form the recesses 310. An exposure tool may be used to expose the photoresist layer 308 to a radiation source to pattern the photoresist layer 308. A developer tool may be used to develop and remove portions of the photoresist layer 308 to expose the pattern. An etch tool may be used to etch the nitride dielectric layers 302, the oxide dielectric layers 304, and the bonding dielectric layer 306 based on the pattern to form the recesses 310. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer 308 (e.g., using a chemical stripper, plasma ashing, and/or another technique).

As shown in FIG. 3F, trench portions of the recesses 310 are formed through the nitride dielectric layers 302, the oxide dielectric layers 304, and the bonding dielectric layer 306. Thus, the recesses 310 may be dual damascene recesses that have a via portion and a trench portion. Moreover, recesses 312 (e.g., single damascene recesses) may be formed in the nitride dielectric layers 302, the oxide dielectric layers 304, and the bonding dielectric layer 306.

In some implementations, a pattern in a photoresist layer 314 is used to etch the nitride dielectric layers 302, the oxide dielectric layers 304, and the bonding dielectric layer 306 to form the trench portion of the recesses 310 and to form the recesses 312. A deposition tool may be used to deposit the photoresist layer 314 on the bonding dielectric layer 306 and in the via portions of the recesses 310. An exposure tool may be used to expose the photoresist layer 314 to a radiation source to pattern the photoresist layer 314. A developer tool may be used to develop and remove portions of the photoresist layer 314 to expose the pattern. An etch tool may be used to etch the nitride dielectric layers 302, the oxide dielectric layers 304, and the bonding dielectric layer 306 based on the pattern to form the trench portion of the recesses 310 and to form the recesses 312. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer 314 (e.g., using a chemical stripper, plasma ashing, and/or another technique).

As shown in FIG. 3G, bonding vias 134 may be formed in the via portions of the recesses 310, and bonding pads 132 may be formed in the trench portions of the recesses 310 and in the recesses 312. A deposition tool may be used to deposit the bonding vias 134 and the bonding pads 132 using a CVD technique, a PVD technique, an ALD technique, an electroplating technique, and/or another suitable deposition technique. The bonding vias 134 and the bonding pads 132 may be deposited in one or more deposition operations. In some implementations, a seed layer is first deposited, and the bonding vias 134 and the bonding pads 132 are deposited on the seed layer.

As shown in FIG. 3H, a planarization tool is used to perform a planarization operation (e.g., a CMP operation) to planarize the bonding pads 132 after the bonding pads 132 are deposited. As further shown in FIG. 3H, the bonding vias 134 in the seal ring region 140 are electrically coupled and/or physically coupled with a conductive structure 130 in the seal ring region 140, and the bonding pads 132 in the seal ring region 140 are electrically coupled and/or physically coupled with the bonding vias 134 in the seal ring region 140. This provides a continuous barrier between the conductive structures 130 and the bonding pads 132 in the seal ring region 140 around the device region 138.

As indicated above, FIGS. 3A-3H are provided as an example. Other examples may differ from what is described with regard to FIGS. 3A-3H.

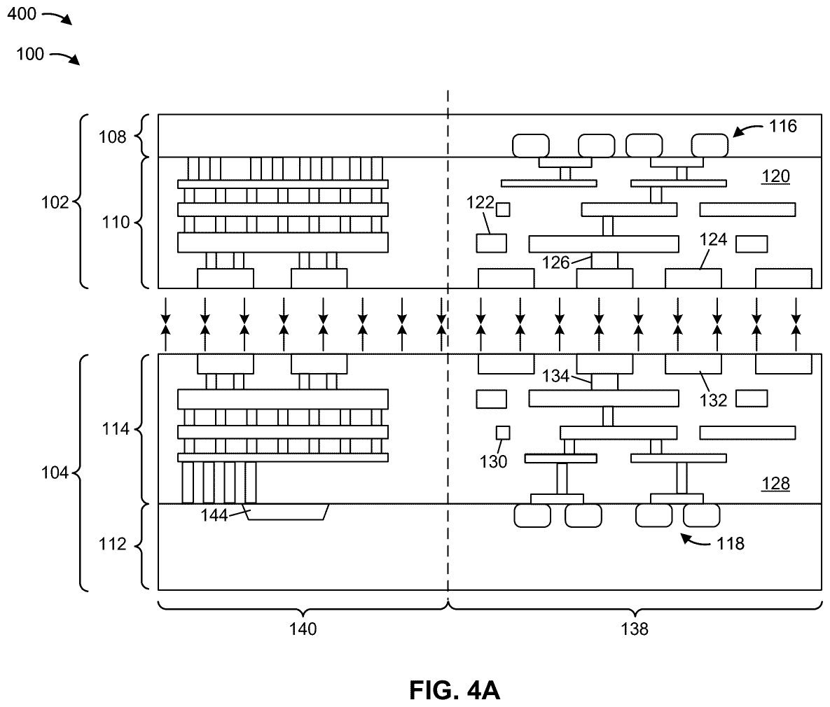

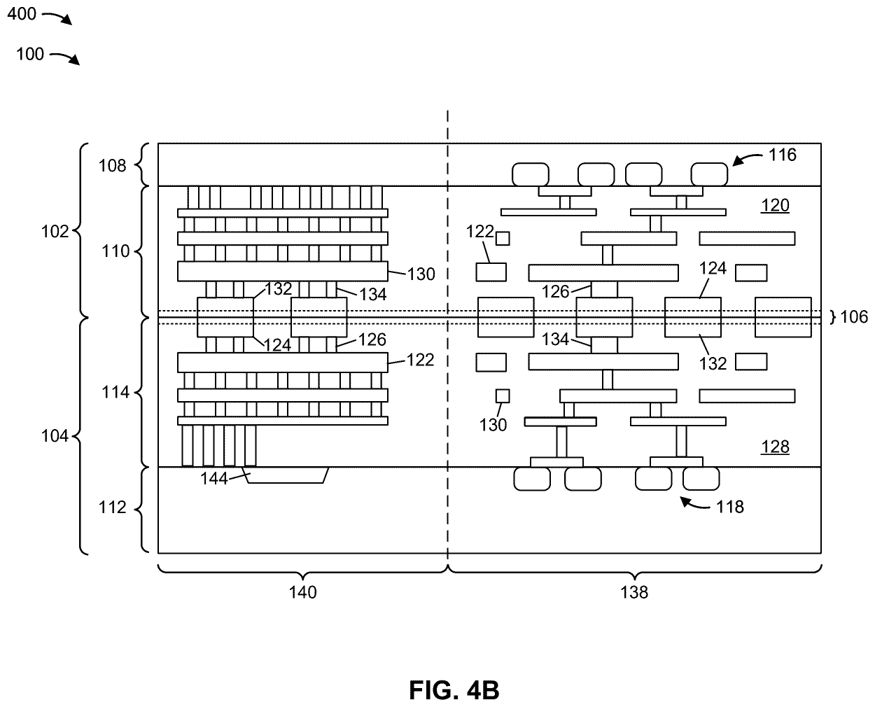

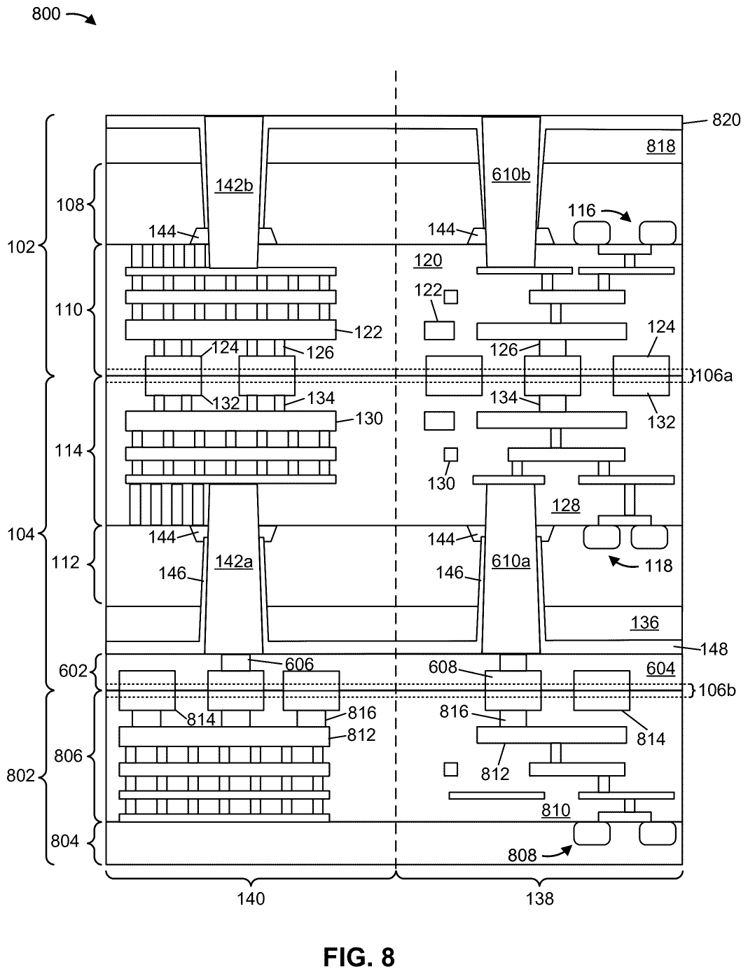

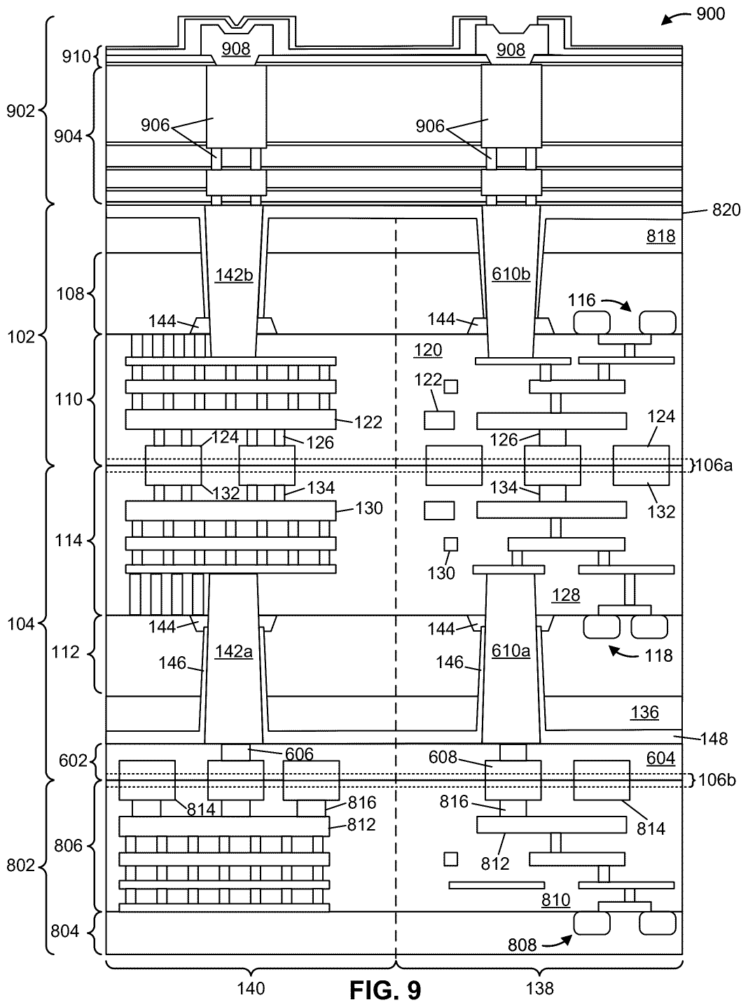

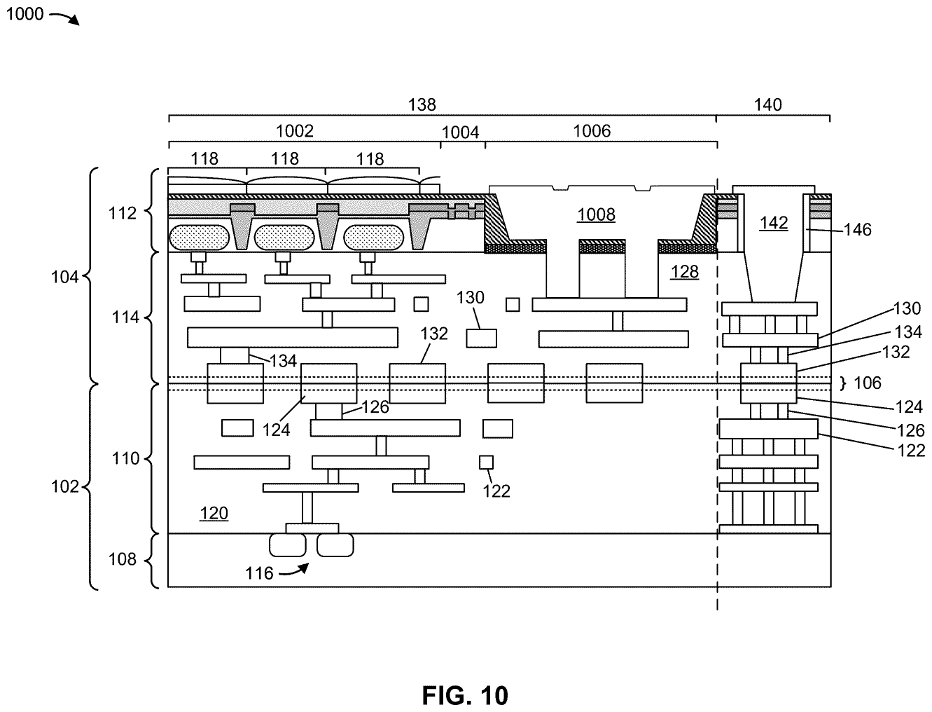

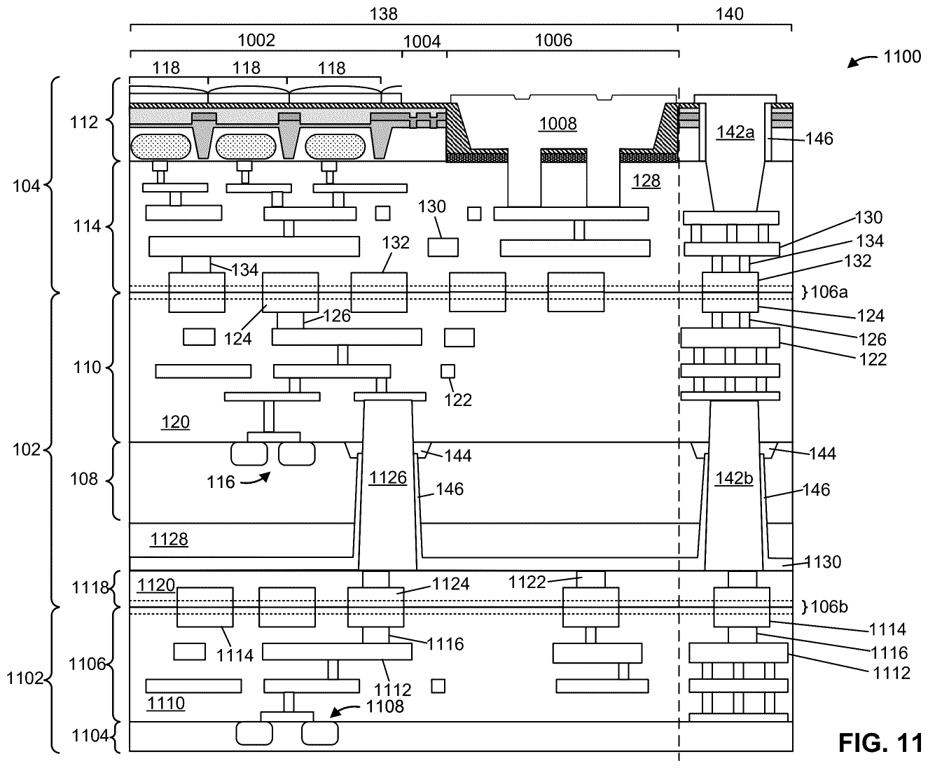

FIGS. 4A and 4B are diagrams of an example implementation 400 of forming a semiconductor package described herein. For example, the example implementation 400 may include an example of forming a semiconductor package 100. In some implementations, one or more of the operations described in connection with the example implementation 400 may be performed to form another semiconductor package described herein, such as a semiconductor package 600 illustrated in FIG. 6, a semiconductor package 800 illustrated in FIG. 8, a semiconductor package 900 illustrated in FIG. 9, a semiconductor package 1000 illustrated in FIG. 10, and/or a semiconductor package 1100 illustrated in FIG. 11, among other examples. In some implementations, one or more semiconductor processing tools may be used to perform one or more of the operations described in connection with the example implementation 400, such as a deposition tool, an exposure tool, a developer tool, an etch tool, a planarization tool, a plating tool, and/or another type of semiconductor processing tool.

As shown in FIGS. 4A and 4B, a bonding operation is performed to bond the semiconductor die 102 and the semiconductor die 104 at the bonding interface 106 such that the semiconductor die 102 and the semiconductor die 104 are vertically arranged or stacked in the semiconductor package 100. The semiconductor die 102 and the semiconductor die 104 may be vertically arranged or stacked in a wafer-on-wafer (WoW) configuration, a die-on-wafer configuration, a die-on-die configuration, and/or another direct bonding configuration. A bonding tool may be used to perform the bonding operation to bond the semiconductor die 102 and the semiconductor die 104 at the bonding interface 106. The bonding operation may include forming a direct bond between the semiconductor die 102 and the semiconductor die 104 through a direct physical connection of the bonding pads 132 of the semiconductor die 102 with the bonding pads 124 of the semiconductor die 104, and through a direct physical connection of one or more of the dielectric layers 120 of the semiconductor die 102 with one or more dielectric layers 128 of the semiconductor die 104.

As further shown in FIG. 4B, the bonding pads 124 and 132 are bonded together in the seal ring region 140 to form a continuous barrier between and through the seal ring portions of the semiconductor dies 102 and 104. In some implementations, the bonding pads 124 are each bonded with a respective bonding pad 132. In some implementations, a bonding pad 124 is bonded with two or more bonding pads 132 and/or one or more of the dielectric layers 120 of the semiconductor die 102. In some implementations, the bonding pads 132 are each bonded with a respective bonding pad 124. In some implementations, a bonding pad 132 is bonded with two or more bonding pads 124 and/or one or more of the dielectric layers 128 of the semiconductor die 104.

As indicated above, FIGS. 4A and 4B are provided as an example. Other examples may differ from what is described with regard to FIGS. 4A and 4B.

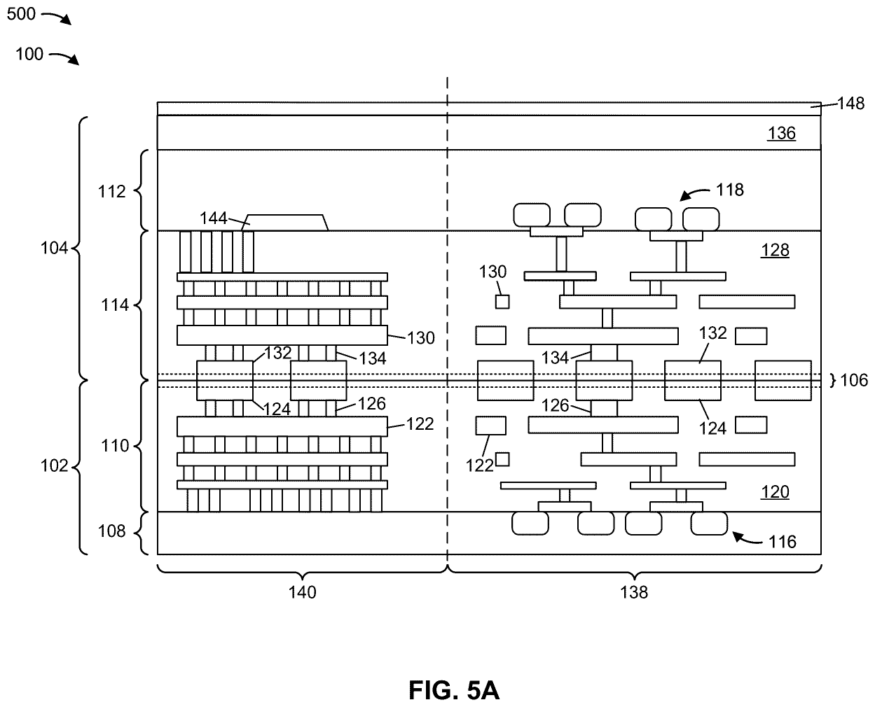

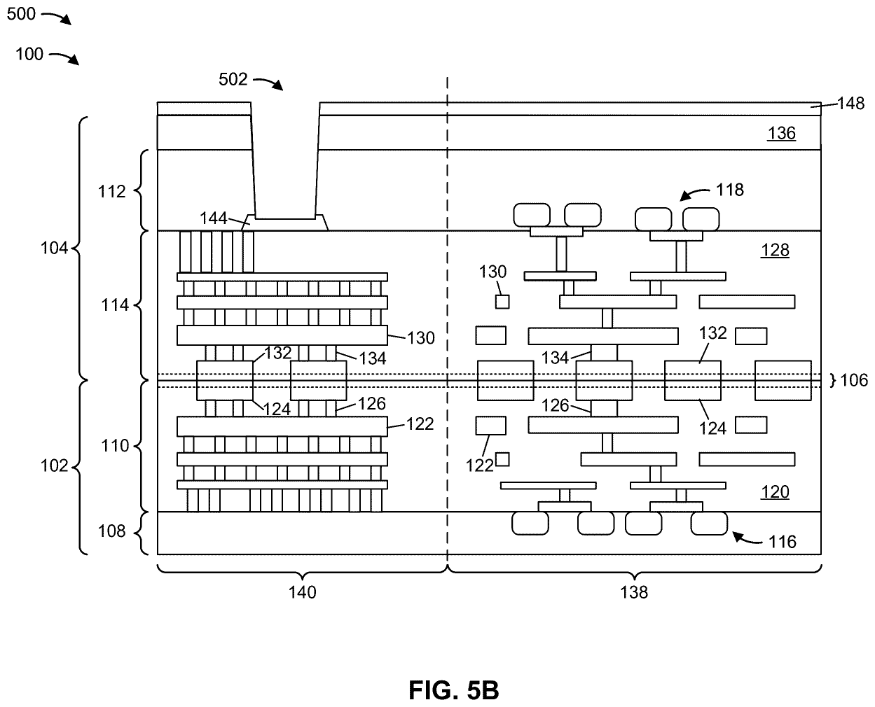

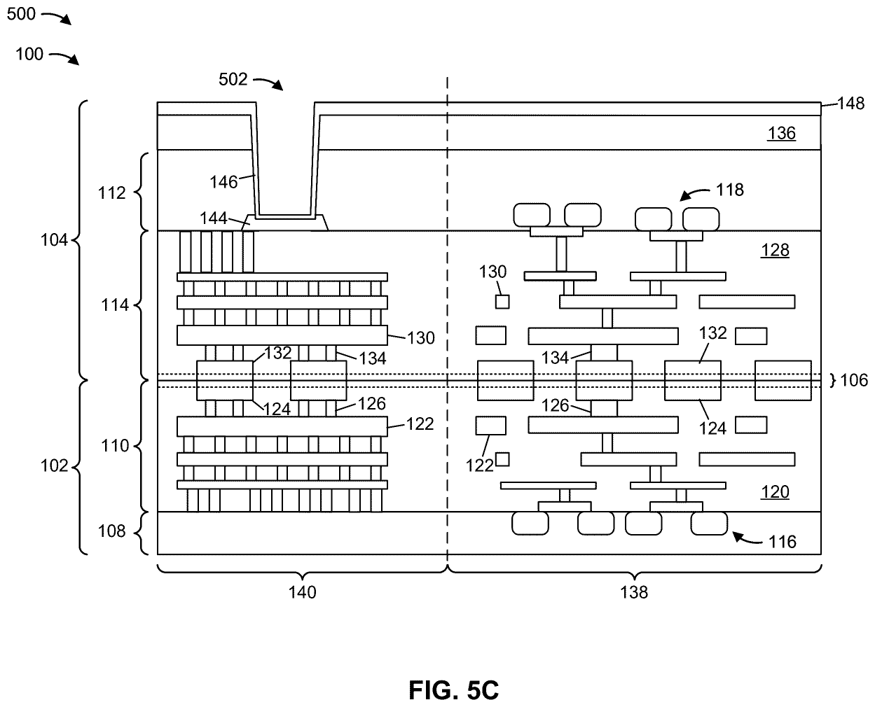

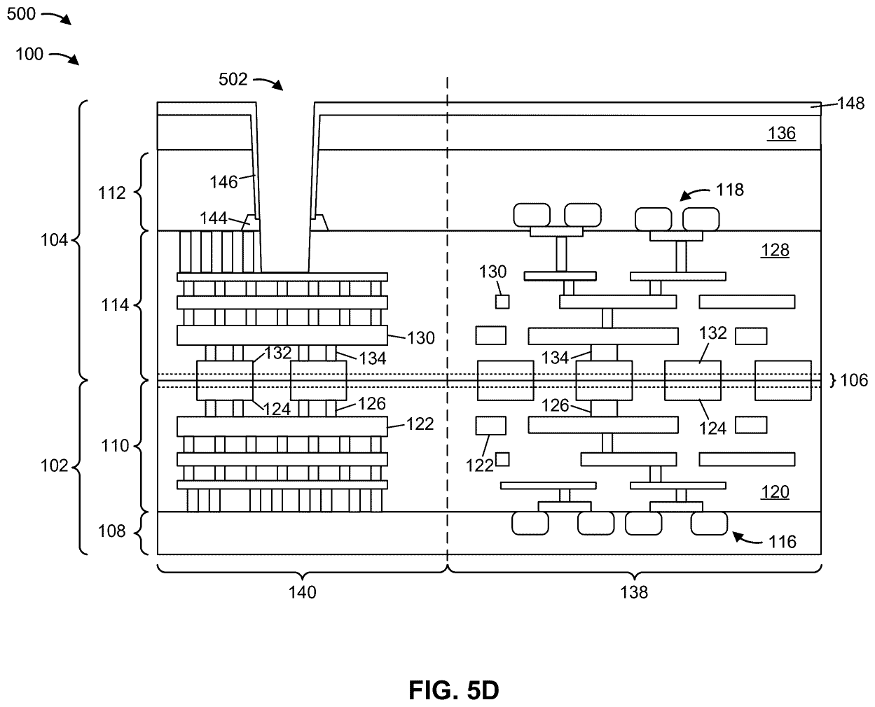

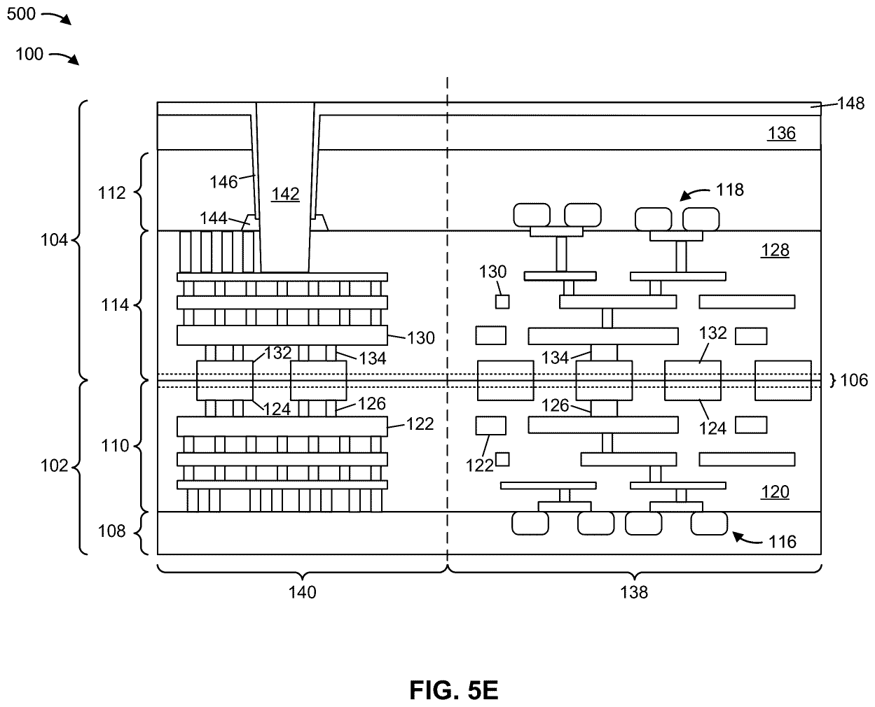

FIGS. 5A-5E are diagrams of an example implementation 500 of forming a through-substrate isolation structure 142 in a seal ring region 140 described herein. While the example implementation 500 is illustrated in connection with forming the through-substrate isolation structure 142 through the semiconductor layer 112 of the semiconductor die 104, one or more of the operations described in connection with the example implementation 500 may be performed to form a through-substrate isolation structure 142 through a semiconductor layer of another semiconductor die described herein (e.g., a semiconductor layer 108 of a semiconductor die 102, a semiconductor layer 804 of a semiconductor die 802 illustrated in FIG. 8). In some implementations, one or more semiconductor processing tools may be used to perform one or more of the operations described in connection with the example implementation 500, such as a deposition tool, an exposure tool, a developer tool, an etch tool, a planarization tool, a plating tool, and/or another type of semiconductor processing tool.

Turning to FIG. 5A, the semiconductor processing operations described in connection with FIGS. 5A-5H may be performed in connection with the back side of the semiconductor layer 112 of the semiconductor die 104. The semiconductor processing operations described in connection with FIGS. 5A-5H may be performed after front side processing of the semiconductor die 104.

As shown in FIG. 5A, a passivation layer 136 may be formed on the back side of the semiconductor layer 112, and a buffer layer 148 may be formed on the passivation layer 136. The passivation layer 136 may be formed to passivate damage that may have occurred during a wafer grinding operation that was performed on the back side of the semiconductor layer 112 to reduce the thickness of the semiconductor layer 112. A deposition tool may be used to deposit each of the passivation layer 136 and the buffer layer 148 using a CVD technique, a PVD technique, an ALD technique, an oxidation technique, and/or another suitable conformal deposition technique. In some implementations, a planarization tool is used to perform the wafer grinding operation to grind the back side of the semiconductor layer. The buffer layer(s) 148 may be included to protect the passivation layer 136 during a self-aligned etch for forming the recess for the through-substrate isolation structure 142, and during a planarization to planarize the through-substrate isolation structure 142, among other examples.

As shown in FIG. 5B, a recess 502 is formed into the semiconductor layer 112 in the seal ring region 140. In some implementations, a pattern may be formed in a masking layer on the buffer layer 148, and the pattern may be used to etch the semiconductor layer 112 to form the recess 502. To form the pattern, an exposure tool may be used to expose the masking layer to a radiation source to pattern the masking layer. A developer tool may be used to develop and remove portions of the masking layer to expose the pattern.

An etch tool may be used to perform an etch operation to etch the semiconductor layer 112 based on the pattern in the masking layer. The semiconductor layer 112 may be etched from the back side of the semiconductor layer 112 to form the recess 502 in the back side of the semiconductor layer 112. The recess 502 may be etched to a first depth in the semiconductor layer 112. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

In some implementations, the etch operation stops on the STI region 144. In some implementations, the etch operation continues into a portion of the STI region 144 to ensure that the liners that are to be formed in the recess 502 provide a continuous dielectric barrier on the semiconductor layer 112. In some implementations, the etch operation includes etching through the STI region 144 and into the dielectric layer(s) 128 of the interconnect layer 114 on the front side of the semiconductor layer 112.

As shown in FIGS. 5C, one or more liners 146 are formed on the sidewalls (and in some cases, on the bottom surface) of the recess 502. In implementations in which the recess 502 is formed into a portion of the STI region 144, the one or more liners 146 may be formed on a portion of the sidewalls of the recess 502 that correspond to the STI region 144. A deposition tool may be used to deposit the one or more liners 146 using an ALD technique, a CVD technique, and/or another suitable conformal deposition technique.

As shown in FIG. 5D, another etch operation may be performed to etch through the STI region 144 and into the dielectric layer 128 to an underlying conductive structure 130 in the seal ring region 140 to expose the conductive structure 130 through the recess 502. Thus, the depth of the recess 502 is increased from the first depth to a second depth during the etch operation. In some implementations, the etch operation includes a dry etch operation (e.g., a plasma-based etch operation, a gas-based etch operation), a wet chemical etch operation, and/or another type of etch operation. In some implementations, the etch operation is performed as a self-aligned etch operation in that the recess 502 is etched without an additional patterned masking layer.

As shown in FIG. 5E, the through-substrate isolation structure 142 may be formed in the recess 502 such that the through-substrate isolation structure 142 lands on the underlying conductive structure 130 in the seal ring region 140. A deposition tool may be used to deposit the through-substrate isolation structure 142 using a CVD technique, a PVD technique, an ALD technique, an electroplating technique, and/or another suitable deposition technique. The through-substrate isolation structure 142 may be deposited in one or more deposition operations. In some implementations, a seed layer is first deposited, and the through-substrate isolation structure 142 is deposited on the seed layer. In some implementations, a planarization tool is used to perform a planarization operation (e.g., a CMP operation) to planarize the through-substrate isolation structure 142 after the through-substrate isolation structure 142 is deposited. In some implementations, a diffusion barrier layer is formed on the through-substrate isolation structure 142 after the through-substrate isolation structure 142 is formed.

As indicated above, FIGS. 5A-5E are provided as an example. Other examples may differ from what is described with regard to FIGS. 5A-5E.

FIG. 6 is a diagram of an example semiconductor package 600 described herein. As shown in FIG. 6, the semiconductor package 600 includes a similar combination and arrangement of structures and layers as the semiconductor package 100. For example, the semiconductor package 600 includes the semiconductor die 102 and the semiconductor die 104 bonded at a bonding interface. The semiconductor package 600 similarly includes a through-substrate isolation structure 142 through the semiconductor layer 112 of the semiconductor die 104. The through-substrate isolation structure 142 is formed in the seal ring region 140 of the semiconductor package 600 using techniques described herein, such as in connection with FIGS. 5A-5E, among other examples.

As further shown in FIG. 6, the semiconductor die 104 may include another interconnect layer 602. The interconnect layer 114 may be located on a first side (e.g., a front side) of the semiconductor layer 112 of the semiconductor die 104, and the interconnect layer 602 may be located on a second side (e.g., a back side) of the semiconductor layer 112 opposite the first side. The interconnect layer 114 may be configured to route signals and/or power between the semiconductor dies 102 and 104, and/or may be configured to route signals and/or power between integrated circuit devices 118 of the semiconductor die 104. The interconnect layer 602 may be configured to route signals and/or power between the semiconductor die 104 and devices external to the semiconductor package 600. For example, the interconnect layer 602 may be configured to route signals and/or power between the semiconductor die 104 and an external high bandwidth memory (HBM) die, an external system on chip (SoC) die, an external input/output (I/O) die, and/or another type of device external to the semiconductor package 600.

The interconnect layer 602 of the semiconductor die 104 includes one or more dielectric layers 604 (e.g., ILD layers, IMD layers, ESLs) and conductive structures 606 (e.g., trenches, metallization layers, vias, interconnect structures) in the dielectric layer(s) 604. The dielectric layer(s) 604 may each include an oxide (e.g., a silicon oxide (SiOₓ) and/or another oxide material), a USG, a BSG, an FSG, an ELK dielectric material, a silicon nitride (SiₓN_{y}), silicon carbide (SiC), silicon oxynitride (SiON), and/or another suitable dielectric material. The conductive structures 606 may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The interconnect layer 602 further includes connection structures 608 that enable the semiconductor package 600 to be attached to a substrate (e.g., an interposer, a printed circuit board (PCB)), another semiconductor package, and/or to be attached to another structure. The connection structures 608 may include bonding pads, solder pads, solder balls, micro-bumps, and/or another type of connection structures.

As further shown in FIG. 6, the through-substrate isolation structure 142 extends through the semiconductor layer 112 and may be physically coupled with a conductive structure 130 in the interconnect layer 114 at a first end of the through-substrate isolation structure 142, and is physically coupled with a conductive structure 606 in the interconnect layer 602 at a second end of the through-substrate isolation structure 142 opposing the first end. This enables the barrier in the seal ring region 140 to extend through the interconnect layer 602 to provide electrical isolation and/or protection from humidity and other contaminants for the device region 138.

The semiconductor package 600 also includes one or more elongated conductive structures 610 in the device region 138. An elongated conductive structure 610 may extend between the interconnect layers 114 and 602 through the semiconductor layer 112 of the semiconductor die 104. An elongated conductive structure 610 may be included in the device region 138 to enable signals and/or power to be provided between the interconnect layers 114 and 602 through the elongated conductive structure 610.

An elongated conductive structure 610 may include a TSV, a metal pillar, a metal column, and/or other another type of vertically elongated conductive structure that physically connects and electrically connects with a conductive structure 130 (e.g., a metal pad) in the interconnect layer 114 at a first end, and that physically connects and electrically connects with a conductive structure 606 (e.g., a metal pad) in the interconnect layer 602. An elongated conductive structure 610 may be referred to as a TSV structure in that the elongated conductive structure 610 extends fully through a semiconductor layer (e.g., a silicon substrate) of the semiconductor layer 112, as opposed to extending fully through a dielectric layer or an insulator layer. An elongated conductive structure 610 may further extend through an STI region 144 that is included in the semiconductor layer of the semiconductor layer 112, and one or more liners 146 may be included between the elongated conductive structure 610 and the semiconductor layer 112.

An elongated conductive structure 610 may include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive material. An elongated conductive structure 610 may be formed using techniques described herein, such as in connection with FIGS. 5A-5E, among other examples.

As indicated above, FIG. 6 is provided as an example. Other examples may differ from what is described with regard to FIG. 6.

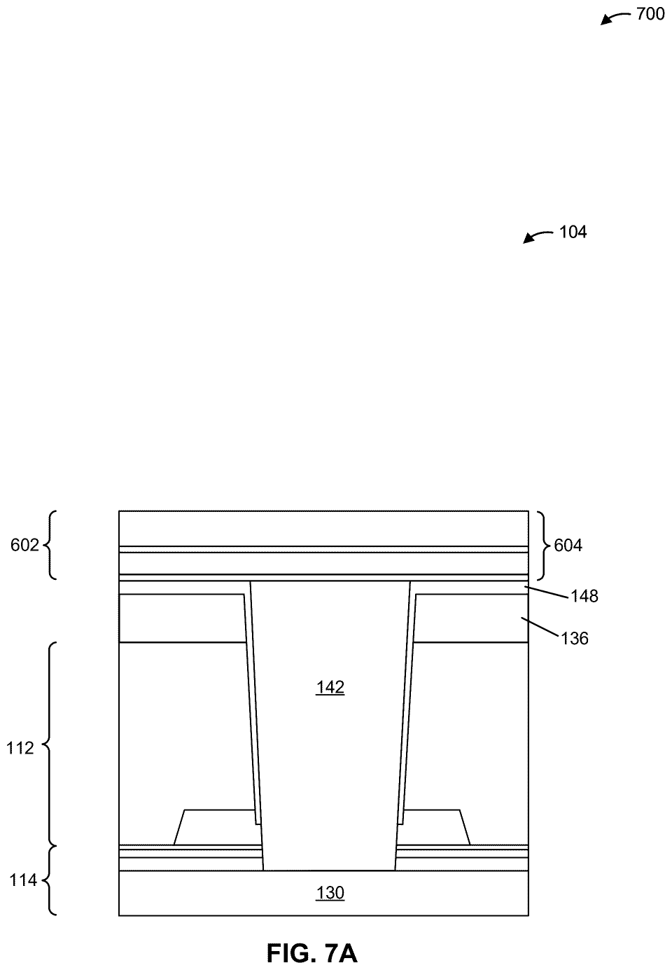

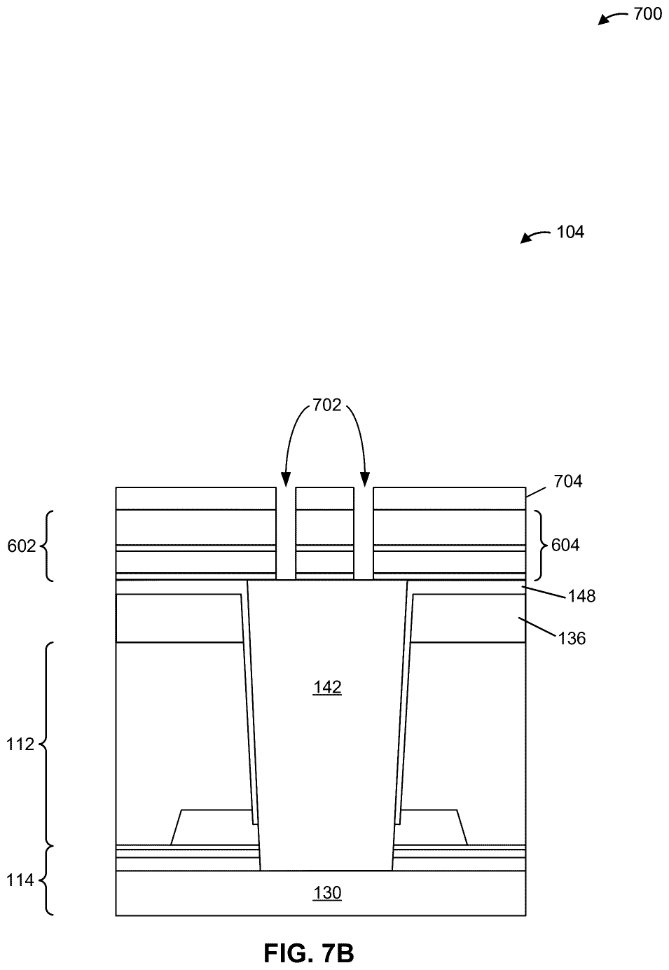

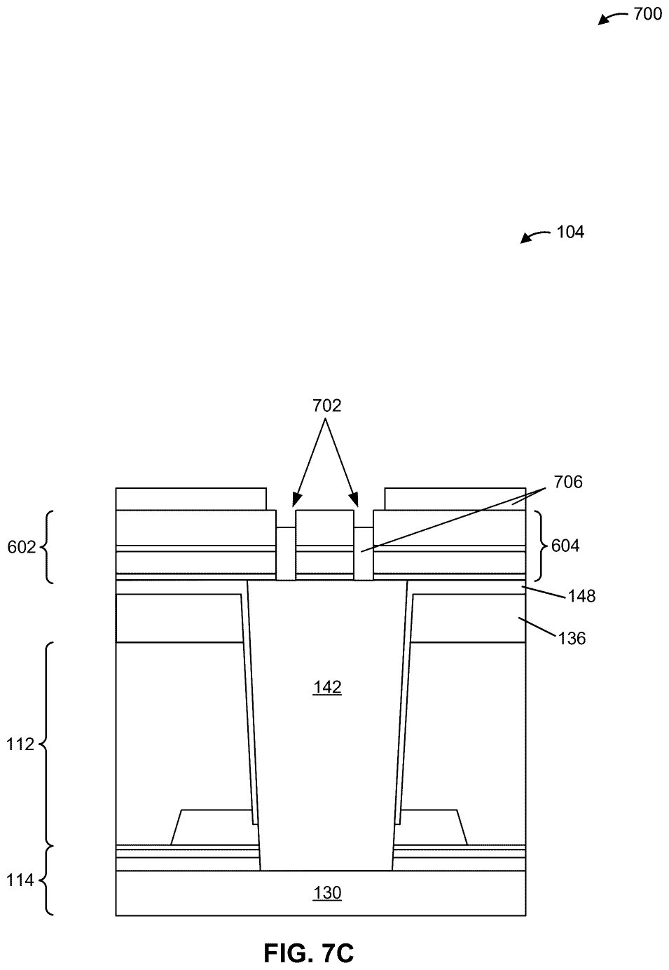

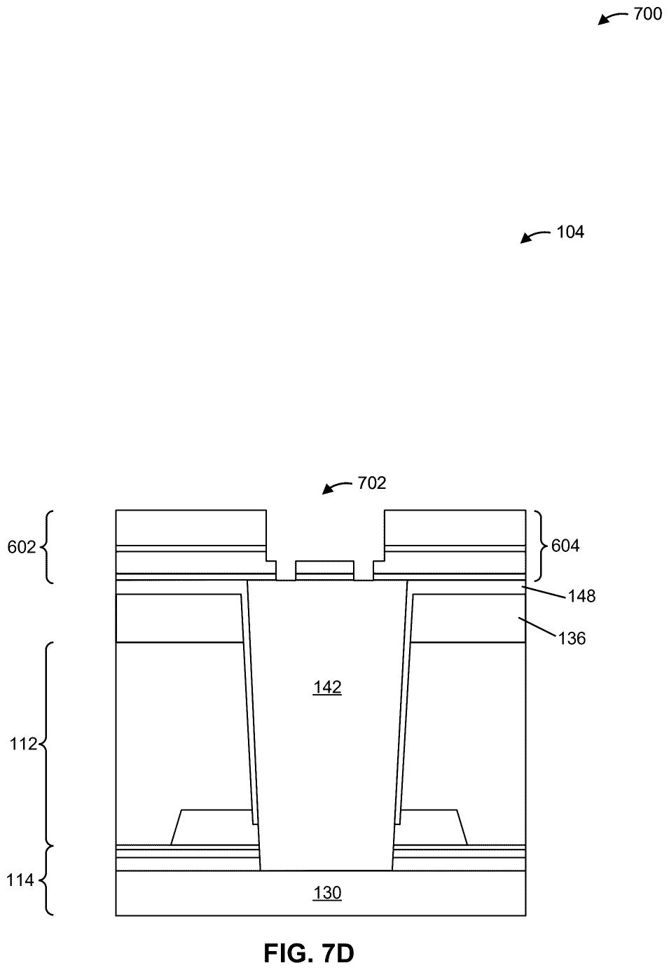

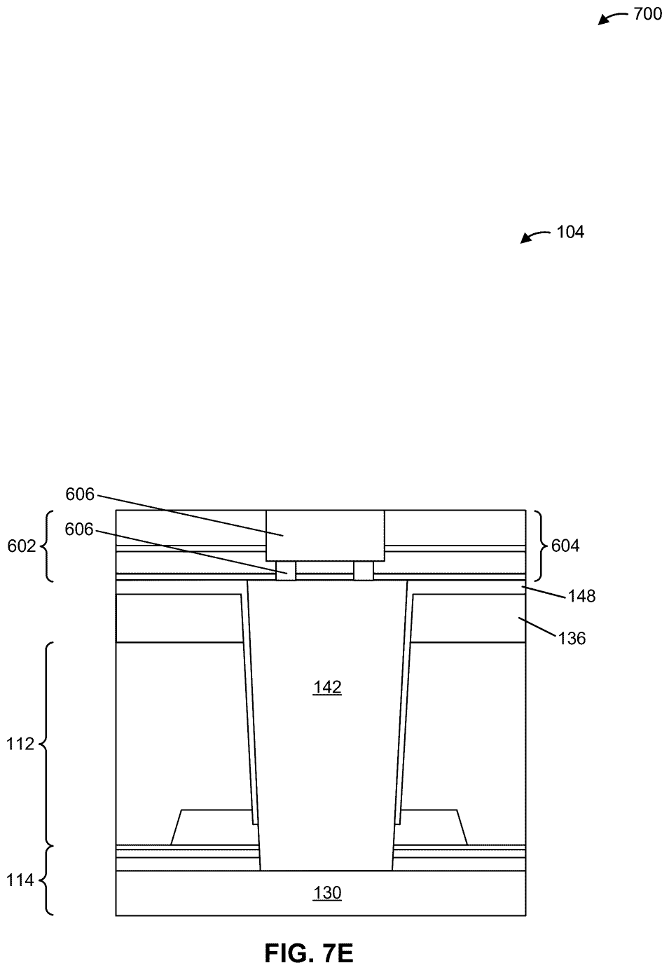

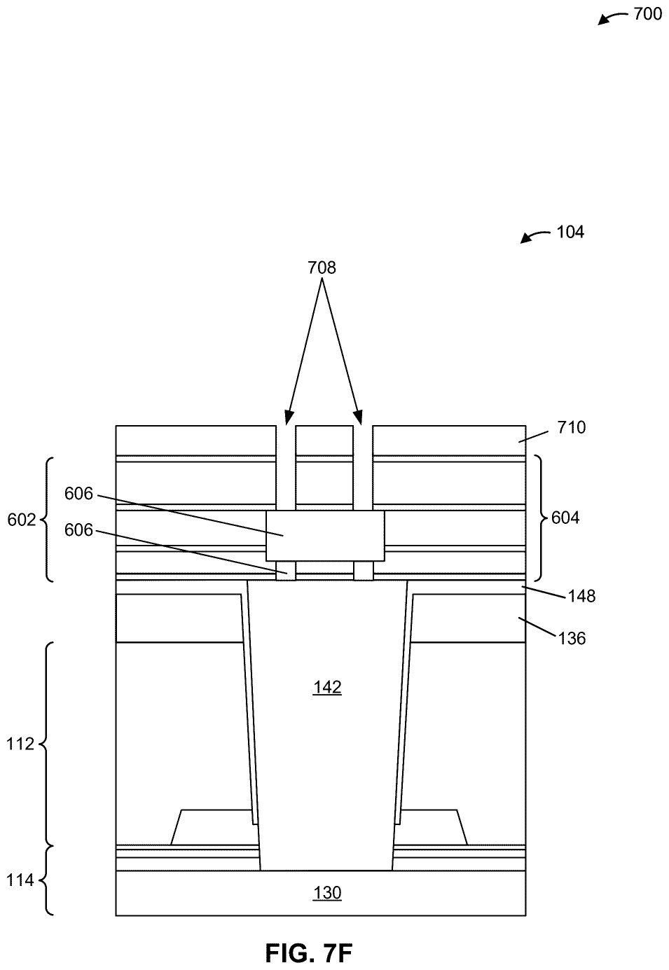

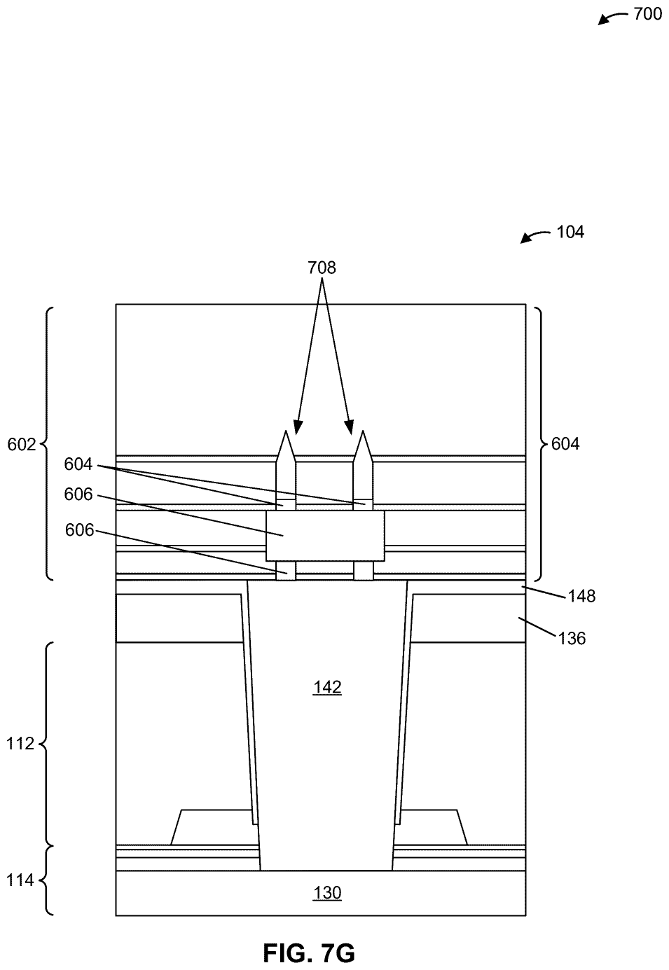

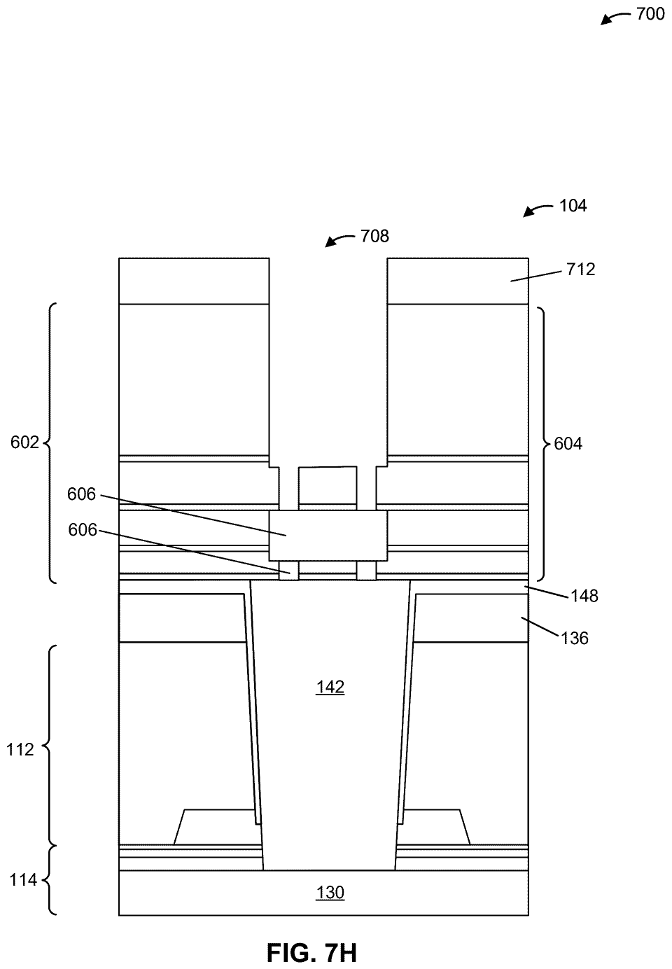

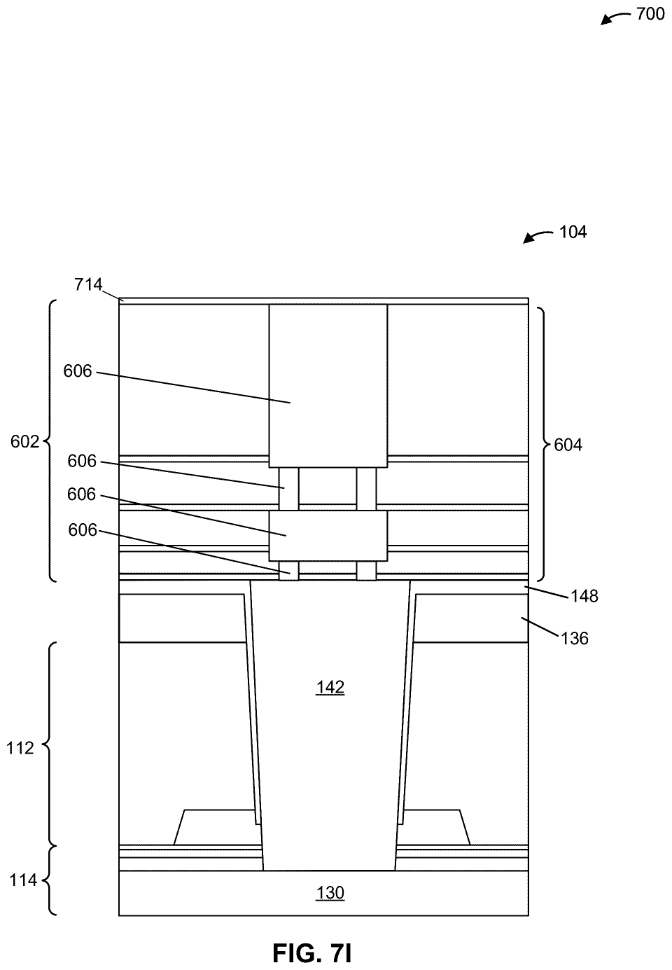

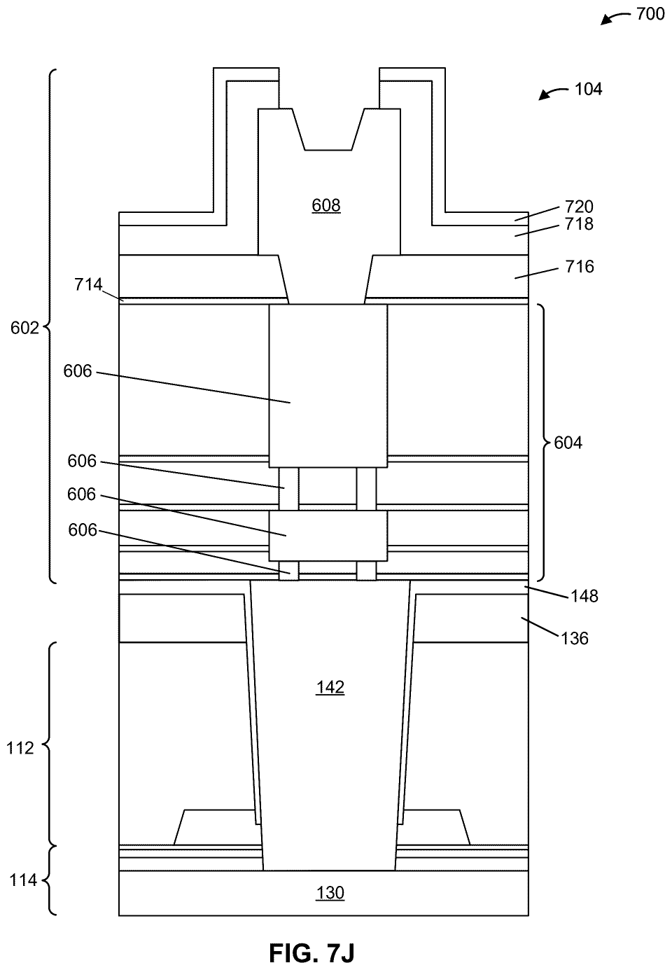

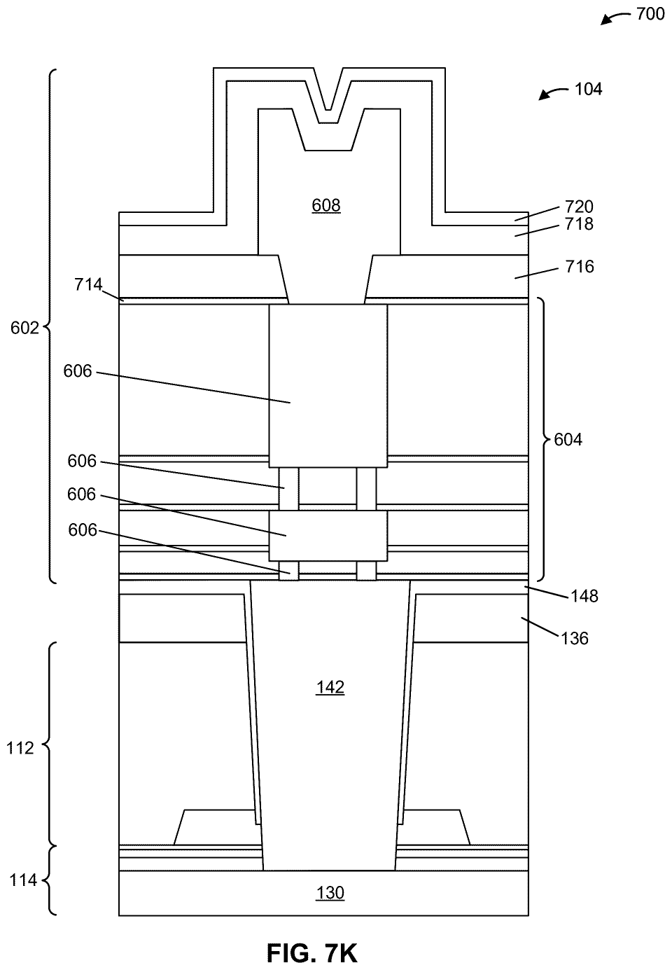

FIGS. 7A-7K are diagrams of an example implementation 700 of forming an interconnect layer 602 of a semiconductor die 104 described herein. In some implementations, one or more semiconductor processing tools may be used to perform one or more of the operations described in connection with the example implementation 700, such as a deposition tool, an exposure tool, a developer tool, an etch tool, a planarization tool, a plating tool, and/or another type of semiconductor processing tool.

As shown in FIG. 7A, one or more of the dielectric layers 604 of the interconnect layer 602 may be formed over the back side of the semiconductor layer 112. A deposition tool may be used to deposit the dielectric layer(s) 604 using a PVD technique, an ALD technique, a CVD technique, an oxidation technique, and/or another suitable deposition technique. The dielectric layer(s) 604 may be deposited in one or more deposition operations. In some implementations, a planarization tool may be used to perform a planarization operation (e.g., a CMP operation) to planarize the dielectric layer(s) 604 after the dielectric layer(s) 604 are deposited.

As shown in FIG. 7B, first portions of a recess 702 are formed through the dielectric layer(s) 604 to a through-substrate isolation structure 142 that extends through the semiconductor layer 112. In some implementations, the through-substrate isolation structure 142 is included in a seal ring region 140 of the semiconductor die 104. Additionally and/or alternatively, the recess 702 may be formed over an elongated conductive structure 610 in a device region 138 of the semiconductor die 104. The first portions of the recess 702 may be referred to as via portions of the recess 702. In some implementations, a pattern in a photoresist layer 704 is used to etch the dielectric layer(s) 604 to form the pattern. In these implementations, a deposition tool may be used to form the photoresist layer 704 on the dielectric layer(s) 604 using a spin-coating technique. An exposure tool may be used to expose the photoresist layer 704 to a radiation source to pattern the photoresist layer 704. A developer tool may be used to develop and remove portions of the photoresist layer 704 to expose the pattern. An etch tool may be used to etch the dielectric layer(s) 604 based on the pattern to form the first portions of the recess 702. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer 704 (e.g., using a chemical stripper, plasma ashing, and/or another technique). In some implementations, a hard mask layer is used as an alternative technique for etching the dielectric layer(s) 604 based on a pattern.

As shown in FIG. 7C, another photoresist layer 706 may be formed on the dielectric layer(s) 604 and in the first portions of the recess 702. A deposition tool may be used to form the photoresist layer 706 on the dielectric layer(s) 604 and in the first portions of the recess 702 using a spin-coating technique.

As shown in FIG. 7D, an etch tool may be used to etch the dielectric layer(s) 604 based on a pattern in the photoresist layer 706 to form a second portion of the recess 702. The second portion of the recess 702 corresponds to a trench portion of the recess 702. Accordingly, the recess 702 may include a dual damascene recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer 706 (e.g., using a chemical stripper, plasma ashing, and/or another technique).

As shown in FIG. 7E, one or more conductive structures 606 of the interconnect layer 602 may be formed in the recess 702. For example, one or more vias may be formed in the via portions of the recess 702 such that the one or more vias land on the through-substrate isolation structure 142. As another example, a metallization layer may be formed in the trench portion of the recess 702. A deposition tool may be used to deposit the conductive structure(s) 606 using a CVD technique, a PVD technique, an ALD technique, an electroplating technique, and/or another suitable deposition technique. The conductive structure(s) 606 may be deposited in one or more deposition operations. In some implementations, a seed layer is first deposited, and the conductive structure(s) 606 are deposited on the seed layer. In some implementations, a planarization tool is used to perform a planarization operation (e.g., a CMP operation) to planarize the conductive structure(s) 606 after the conductive structure(s) 606 are deposited.

As shown in FIG. 7F, one or more additional dielectric layers 604 of the interconnect layer 602 may be formed over the back side of the semiconductor layer 112. A deposition tool may be used to deposit the dielectric layer(s) 604 using a PVD technique, an ALD technique, a CVD technique, an oxidation technique, and/or another suitable deposition technique. The dielectric layer(s) 604 may be deposited in one or more deposition operations. In some implementations, a planarization tool may be used to perform a planarization operation (e.g., a CMP operation) to planarize the dielectric layer(s) 604 after the dielectric layer(s) 604 are deposited.

As further shown in FIG. 7F, first portions of a recess 708 are formed through the dielectric layer(s) 604 to the underlying conductive structure 606. The first portions of the recess 708 may be referred to as via portions of the recess 708. In some implementations, a pattern in a photoresist layer 710 is used to etch the dielectric layer(s) 604 to form the pattern. In these implementations, a deposition tool may be used to form the photoresist layer 710 on the dielectric layer(s) 604 using a spin-coating technique. An exposure tool may be used to expose the photoresist layer 710 to a radiation source to pattern the photoresist layer 710. A developer tool may be used to develop and remove portions of the photoresist layer 710 to expose the pattern. An etch tool may be used to etch the dielectric layer(s) 604 based on the pattern to form the first portions of the recess 708. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer 710 (e.g., using a chemical stripper, plasma ashing, and/or another technique). In some implementations, a hard mask layer is used as an alternative technique for etching the dielectric layer(s) 604 based on a pattern.

As shown in FIG. 7G, one or more additional dielectric layers 604 of the interconnect layer 602 may be formed over the back side of the semiconductor layer 112. A deposition tool may be used to deposit the dielectric layer(s) 604 using a PVD technique, an ALD technique, a CVD technique, an oxidation technique, and/or another suitable deposition technique. The dielectric layer(s) 604 may be deposited in one or more deposition operations. In some implementations, a planarization tool may be used to perform a planarization operation (e.g., a CMP operation) to planarize the dielectric layer(s) 604 after the dielectric layer(s) 604 are deposited. The dielectric layer(s) 604 may seal the first portions of the recess 708. In some implementations, some amount of material of the dielectric layer(s) 604 is deposited in the first portions of the recess 708 as the material of the dielectric layer(s) 604 seals the first portions of the recess 708.

As shown in FIG. 7H, an etch tool may be used to etch the dielectric layer(s) 604 based on a pattern in another photoresist layer 712 to form a second portion of the recess 708. The second portion of the recess 708 corresponds to a trench portion of the recess 708. In some implementations, the dielectric layer(s) 604 may be etched such that the trench portion is formed down to the via portions of the recess 708. As the etching proceeds through the dielectric layer(s) 604 to the via portions of the recess 708, the via portions of the recess 708 are opened up, and the material of the dielectric layer(s) 604 that was deposited in the via portions of the recess 708 as described in connection with FIG. 7G is etched and removed. Accordingly, the recess 708 may include a dual damascene recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer 712 (e.g., using a chemical stripper, plasma ashing, and/or another technique).

As shown in FIG. 7I, one or more conductive structures 606 of the interconnect layer 602 may be formed in the recess 708. For example, one or more vias may be formed in the via portions of the recess 708. As another example, a metallization layer may be formed in the trench portion of the recess 708. A deposition tool may be used to deposit the conductive structure(s) 606 using a CVD technique, a PVD technique, an ALD technique, an electroplating technique, and/or another suitable deposition technique. The conductive structure(s) 606 may be deposited in one or more deposition operations. In some implementations, a seed layer is first deposited, and the conductive structure(s) 606 are deposited on the seed layer. In some implementations, a planarization tool is used to perform a planarization operation (e.g., a CMP operation) to planarize the conductive structure(s) 606 after the conductive structure(s) 606 are deposited.

As further shown in FIG. 7I, a barrier layer 714 is formed on the conductive structure(s) 606 to prevent, minimize, and/or otherwise reduce the likelihood of upward material migration from the conductive structure(s) 606 to structures that are subsequently formed above the conductive structure(s) 606. The barrier layer 714 may also function as an etch stop layer for etching layers that are subsequently formed above the conductive structure(s) 606. The barrier layer 714 may include silicon nitride (SiₓN_{y}), tantalum nitride (TaN), and/or another suitable barrier material. A deposition tool may be used to deposit the barrier layer 714 using a CVD technique, a PVD technique, an ALD technique, and/or another suitable deposition technique.

As shown in FIG. 7J, one or more backside passivation layers 716 are formed above the back side of the semiconductor layer 112. Connection structures 608 may be formed through the backside passivation layer(s) 716 and the barrier layer 714 such that the connection structures 608 are coupled to one or more conductive structures 606 in the interconnect layer 602. Additional backside passivation layers 718 and/or 720 may be formed over the connection structures 608. In the example implementation in FIG. 7J, the backside passivation layers 718 and 720 are opened to expose the connection structures 608 in the seal ring region 140, similar to as what is done for the connection structures 608 in the device region 138. FIG. 7K illustrates an alternative embodiment in which the backside passivation layers 718 and 720 are not opened in the seal ring region 140 such that the connection structures 608 in the seal ring region 140 remain covered by the backside passivation layers 718 and 720. In the example implementation in FIG. 7K, the connection structures 608 in the device region 138 may still be opened as shown in FIG. 7J.

As indicated above, FIGS. 7A-7K are provided as an example. Other examples may differ from what is described with regard to FIGS. 7A-7K.

FIG. 8 is a diagram of an example semiconductor package 800 described herein. As shown in FIG. 8, the semiconductor package 800 includes a similar combination and arrangement of structures and layers as the semiconductor package 600. For example, the semiconductor package 800 includes the semiconductor die 102 and the semiconductor die 104 bonded at a bonding interface. The device region 138 of the semiconductor package 800 similarly includes an elongated conductive structure 610a through the semiconductor layer 112 of the semiconductor die 104, and the seal ring region 140 similarly includes a through-substrate isolation structure 142a through the semiconductor layer 112 of the semiconductor die 104. The through-substrate isolation structure 142a and the elongated conductive structure 610a may each be formed using techniques described herein, such as in connection with FIGS. 5A-5E, among other examples.

However, as shown in FIG. 8, the semiconductor package 800 may include an additional semiconductor die 802 that is bonded with the semiconductor die 104 at another bonding interface. Thus, the semiconductor die 104 is bonded with the semiconductor die 102 at a bonding interface 106a located on a front side of the semiconductor layer 112, and bonded with the semiconductor die 802 at a bonding interface 106b located on a back side of the semiconductor layer 112. The semiconductor die 102, the semiconductor die 104, and the semiconductor die 802 are vertically arranged in a three-die stacking arrangement in the semiconductor package 800. The semiconductor die 102 and the semiconductor die 104 may be bonded at the bonding interface 106a, and the semiconductor die 104 and the semiconductor die 802 may be bonded at the bonding interface 106b, using similar bonding techniques as described in connection with FIGS. 4A and 4B.

The semiconductor die 802 may include a semiconductor layer 804, an interconnect layer 806, one or more integrated circuit devices 808 in the semiconductor layer 804, one or more dielectric layers 810 and a plurality of conductive structures 812 in the interconnect layer 806, and bonding pads 814 that are bonded with the connection structures 608 (which may also be implemented as bonding pads in the semiconductor package 800) at the bonding interface 106b. The bonding pads 814 are electrically coupled to the conductive structures 812 through bonding vias 816.

Each of the semiconductor dies 102, 104, and 802 may include a different functionality. For example, the semiconductor die 102 may include a capacitor die (e.g., a deep trench capacitor (DTC) die), the semiconductor die 104 may include a logic die, and the semiconductor die 802 may include a memory die (e.g., a dynamic random access memory (DRAM) die). Alternatively, two or more of the semiconductor dies 102, 104, and/or 802 may include similar functionality.

The elongated conductive structure 610a in the device region 138 may enable signals and/or power to be provided between the interconnect layer 114 of the semiconductor die 104 and the interconnect layer 806 of the semiconductor die 802. In some implementations, the elongated conductive structure 610a in the device region 138 may enable signals and/or power to be provided between the interconnect layer 110 of the semiconductor die 102 and the interconnect layer 806 of the semiconductor die 802 through the interconnect layer 114 of the semiconductor die 104.

As further shown in FIG. 8, semiconductor die 102 may include an additional through-substrate isolation structure 142b that extends into and/or through the semiconductor layer 108 of the semiconductor die 102 in the seal ring region 140, and may include an additional elongated conductive structure 610b that extends through the semiconductor layer 108 of the semiconductor die 102 in the device region 138. The through-substrate isolation structure 142b in the seal ring region 140 of the semiconductor package 800 may extend the barrier that laterally surrounds the device region 138. In the example in FIG. 8, the through-substrate isolation structure 142b and/or the elongated conductive structure 610b may extend through an STI region 144 in the semiconductor layer 108 and into the interconnect layer 110 for physical and/or electrical coupling with the conductive structures 122. Alternatively, the through-substrate isolation structure 142b may terminate in an STI region 144 in the semiconductor layer 108. A passivation layer 818 and/or a buffer layer 820 may be included on the back side of the semiconductor layer 108.

In some implementations, the through-substrate isolation structure 142a and the through-substrate isolation structure 142b include the same material or the same material composition. For example, the through-substrate isolation structure 142a and the through-substrate isolation structure 142b may both include copper (Cu) structures. In some implementations, the through-substrate isolation structure 142a and the through-substrate isolation structure 142b include different materials or different material compositions. For example, the through-substrate isolation structure 142a may include a copper (Cu) structure, and the through-substrate isolation structure 142b may include an aluminum copper (AlCu) structure. The elongated conductive structures 610a and 610b and the through-substrate isolation structures 142a and 142b, may each be formed using techniques described herein, such as in connection with FIGS. 5A-5E, among other examples.

The seal ring region 140 laterally surrounds the device region 138 of the semiconductor dies 102, 104, and 802. The through-substrate isolation structures 142b and 142a in the seal ring region 140 enables a continuous barrier to extend through the semiconductor dies 102, 104, and 802. The combination of the through-substrate isolation structure 142b and 142a in the seal ring region 140; the conductive structures 122, 130, and 812 in the seal ring region 140; the bonding pads 124, 132, 608 (which may also be referred as the connection structures of the semiconductor die 104) and 814 in the seal ring region 140; and the bonding vias 126, 134, 606 (which may also be referred as the conductive structures of the semiconductor die 104) and 816 in the seal ring region 140 provide a seal around the device region 138 against electrical leakage, external physical stresses and contamination such as humidity.

As indicated above, FIG. 8 is provided as an example. Other examples may differ from what is described with regard to FIG. 8.

FIG. 9 is a diagram of an example semiconductor package 900 described herein. As shown in FIG. 9, the semiconductor package 900 includes a similar combination and arrangement of structures and layers as the semiconductor package 800. For example, the semiconductor package 900 includes the semiconductor die 102 and the semiconductor die 104 bonded at the bonding interface 106a, and the semiconductor die 802 bonded with the semiconductor die 104 at the bonding interface 106b. The semiconductor package 900 similarly includes elongated conductive structures 610a and 610b in the device region 138, and similarly includes through-substrate isolation structures 142a and 142b in the seal ring region 140. The elongated conductive structure 610a and the through-substrate isolation structure 142a each extend through the semiconductor layer 112 of the semiconductor die 104. The elongated conductive structure 610b and the through-substrate isolation structure 142b each extend through the semiconductor layer 108 of the semiconductor die 102. The elongated conductive structures 610a and 610b, and the through-substrate isolation structures 142a and 142b, may each be formed using techniques described herein, such as in connection with FIGS. 5A-5E, among other examples.

The semiconductor package 900 includes an additional interconnect layer 902 on the backside of the semiconductor layer 108 of the semiconductor die 102. The interconnect layer 902 is similar to the example implementation of the interconnect layer 602 illustrated in FIGS. 7A-7K, and may be formed using similar processes and techniques as those described in connection with FIGS. 7A-7K. For example, dielectric layers 904 of the interconnect layer 902, conductive structures 906 of the interconnect layer 902, connection structures 908 of the interconnect layer 902, and passivation layers 910 of the interconnect layer 902 may be formed in a similar order of process operations and using similar techniques as illustrated and described in FIGS. 7A-7K for the dielectric layers 604 of the interconnect layer 602, the conductive structures 606 of the interconnect layer 602, the connection structures 608 of the interconnect layer 602, and the passivation layers 714-720 of the interconnect layer 602. semiconductor package semiconductor package

As further shown in FIG. 9, the passivation layers 910 may be opened above the connection structures 908 in the device region 138 to enable external connections to be made to the connection structures 908 in the device region 138. The passivation layers 910 may be closed over the connection structures 908 in the seal ring region 140 to maintain passivation for the connection structures 908 in the seal ring region 140.

As indicated above, FIG. 9 is provided as an example. Other examples may differ from what is described with regard to FIG. 9.

FIG. 10 is a diagram of an example semiconductor package 1000 described herein. As shown in FIG. 10, the semiconductor package 1000 includes a similar combination and arrangement of structures and layers as the semiconductor package 100. The through-substrate isolation structure 142 is formed using techniques described herein, such as in connection with FIGS. 5A-5E, among other examples. However, in the semiconductor package 1000, the integrated circuit devices 118 include a plurality of pixel sensors. Thus, the semiconductor die 104 may include an image sensor die such as a complementary metal-oxide-semiconductor (CMOS) image sensor die. Accordingly, the device region 138 of the semiconductor die 104 includes a pixel sensor array 1002 that includes a plurality of pixel sensors (the integrated circuit devices 118), a black level correction (BLC) region 1004, and a bonding pad region 1006 on the back side of the semiconductor layer 112. The seal ring region 140 is adjacent to device region 138 (e.g., adjacent to the bonding pad region 1006 in the device region 138). The through-substrate isolation structure 142 in the seal ring region 140 may laterally surround the pixel sensor array 1002 in the semiconductor layer 112.

The pixel sensors in the pixel sensor array 1002 are configured to sense and/or accumulate incident light and to generate a photocurrent based on the accumulation of incident light. The BLC region 1004 includes a region of the semiconductor layer 112 (e.g., a sensing region) that is shielded by a metal layer so that dark current measurements may be performed in the BLC region 1004. A dark current measurement may be performed to measure the amount of charge (dark current) in the semiconductor layer 112 that is generated from sources other than incident light (e.g., from thermal energy in the semiconductor layer 112) so that the dark current measurement may be used for black level correction (or black level calibration) for the pixel sensors of the pixel sensor array 1002. The bonding pad region 1006 includes a bonding pad 1008 that enables external connections to be made to the semiconductor package 1000.

The integrated circuit devices 116 of the semiconductor die 102 may include one or more application-specific integrated circuit (ASIC) devices, one or more system-on-chip (SOC) devices, one or more transistors, and/or one or more other components configured to measure the magnitude of a photocurrent generated by the pixel sensors of the pixel sensor array 1002 to determine light intensity of incident light and/or to generate images and/or video (e.g., digital images, digital video).

As indicated above, FIG. 10 is provided as an example. Other examples may differ from what is described with regard to FIG. 10.

FIG. 11 is a diagram of an example semiconductor package 1100 described herein. As shown in FIG. 11, the semiconductor package 1100 includes a similar combination and arrangement of structures and layers as the semiconductor package 1000, semiconductor package semiconductor package For example, the semiconductor package 1100 includes the semiconductor die 102 bonded to the semiconductor die 104 (e.g., an image sensor die) at a bonding interface 106a. Semiconductor die 104 includes a plurality of integrated circuit devices 118 (e.g., pixel sensors) in a pixel sensor array 1002, a BLC region 1004, and a bonding pad region 1006 in the device region 138 of the semiconductor package 1100. The seal ring region 140 includes a through-substrate isolation structure 142a that extends through the semiconductor layer 112 of the semiconductor die 104 and is coupled to a conductive structure 130 in the interconnect layer 114 of the semiconductor die 104. The integrated circuit devices 116 of the semiconductor die 102 may include one or more ASIC devices, one or more SOC devices, one or more transistors, and/or one or more other components configured to measure the magnitude of a photocurrent generated by the pixel sensors of the pixel sensor array 1002 to determine light intensity of incident light and/or to generate images and/or video (e.g., digital images, digital video).

As further shown in FIG. 11, the semiconductor package 1100 includes an additional semiconductor die 1102 that is bonded with the semiconductor die 102 at another bonding interface 106b. The semiconductor die 1102 may be similar to the semiconductor die 802 in FIGS. 8 and 9, and may include a DRAM die (or another type of memory die) for storing data associated with images and/or video generated by the pixel sensors of the pixel sensor array 1002 and/or another type of semiconductor die. Thus, the semiconductor die 102 is bonded with the semiconductor die 104 at a bonding interface 106a located on a front side of the semiconductor layer 108 and at a front side of the semiconductor layer 112, and bonded with the semiconductor die 1102 at a bonding interface 106b located on a back side of the semiconductor layer 108. The semiconductor die 104, the semiconductor die 102, and the semiconductor die 1102 are vertically arranged in a three-die stacking arrangement in the semiconductor package 1100. The semiconductor die 102 and the semiconductor die 104 may be bonded at the bonding interface 106a, and the semiconductor die 104 and the semiconductor die 1102 may be bonded at the bonding interface 106b, using similar bonding techniques as described in connection with FIGS. 4A and 4B.

The semiconductor die 1102 may include a semiconductor layer 1104, an interconnect layer 1106, one or more integrated circuit devices 1108 in the semiconductor layer 1104, one or more dielectric layers 1110 and a plurality of conductive structures 1112 in the interconnect layer 1106, and bonding pads 1114 that are electrically coupled to the conductive structures 1112 through bonding vias 1116 semiconductor package

The semiconductor die 102 may further include an interconnect layer 1118 on a backside of the semiconductor layer 108. The interconnect layer 1118 may be similar to the interconnect layer 602 in FIGS. 8 and 9, and may include one or more dielectric layers 1120 (similar the dielectric layer(s) 604), conductive structures 1122 (similar to conductive structures 606) in the dielectric layer(s) 1120, and connection structures 1124 (similar to connection structures 608) in the dielectric layer(s) 1120. The interconnect layer 1118 and the associated layers and/or structures included therein may be formed using similar techniques and processes as the interconnect layer 602. The semiconductor die 1102 and the semiconductor die 102 may be bonded at the bonding interface 106b in metal-to-metal bonds between the connection structures 1114 and 1124, and in dielectric-to-dielectric bonds between the dielectric layers 1110 and 1120.

As further shown in FIG. 11, semiconductor die 102 may include an additional through-substrate isolation structure 142b that extends into the semiconductor layer 108 of the semiconductor die 102 in the seal ring region 140, and may include an elongated conductive structure 1126 that extends into the semiconductor layer 108 of the semiconductor die 102 in the device region 138. The through-substrate isolation structure 142b in the seal ring region 140 of the semiconductor package 1100 may extend the barrier that laterally surrounds the device region 138. In the example in FIG. 11, the through-substrate isolation structure 142b and the elongated conductive structure 1126 each extend through an STI region 144 in the semiconductor layer 108. The elongated conductive structure 1126 may be electrically coupled to a conductive structure 122 in the interconnect layer 110, and may be electrically coupled to a conductive structure 1122 in the interconnect layer 1118. The elongated conductive structure 1126 through the semiconductor layer 108 of the semiconductor die 102 in the device region 138 may enable the data associated with the images and/or video to be provided from the semiconductor die 102 to the semiconductor die 1102 (or vice-versa) through the semiconductor layer 108. The through-substrate isolation structure 142b may be electrically coupled to a conductive structure 122 in the interconnect layer 110, and may be electrically coupled to a conductive structure 1122 in the interconnect layer 1118. A passivation layer 1128 and/or a buffer layer 1130 may be included on the back side of the semiconductor layer 108 between the semiconductor layer 108 and the interconnect layer 1118.

In some implementations, the through-substrate isolation structure 142a and the through-substrate isolation structure 142b include the same material or the same material composition. For example, the through-substrate isolation structure 142a and the through-substrate isolation structure 142b may both include copper (Cu) structures. In some implementations, the through-substrate isolation structure 142a and the through-substrate isolation structure 142b include different materials or different material compositions. For example, the through-substrate isolation structure 142a may include an aluminum copper (AlCu) structure, and the through-substrate isolation structure 142b may include a copper (Cu) structure. The through substrate isolation structure 142a and 142b provide a continuous barrier for electrical isolation between and through the seal ring portions of the semiconductor dies 104, 102 and 1102. The bonding pad 1008, elongated conductive structure 1126 and the through-substrate isolation structures 142a and 142b, may each be formed using techniques described herein, such as in connection with FIGS. 5A-5E, among other examples.

As indicated above, FIG. 11 is provided as an example. Other examples may differ from what is described with regard to FIG. 11.

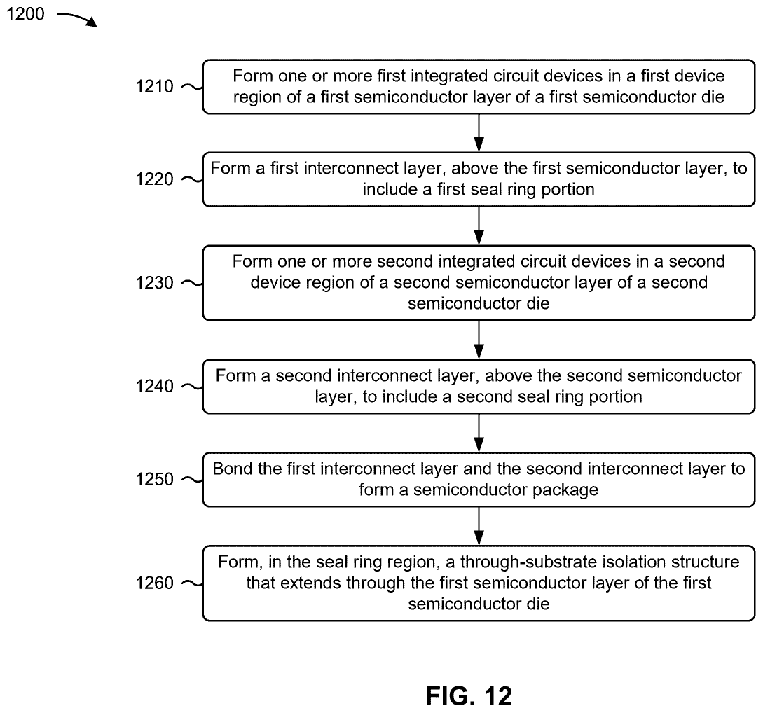

FIG. 12 is a flowchart of an example process 1200 associated with forming a semiconductor package described herein. In some implementations, one or more process blocks of FIG. 12 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 12, process 1200 may include forming one or more first integrated circuit devices in a first device region of a first semiconductor layer of a first semiconductor die (block 1210). For example, one or more semiconductor processing tools may be used to form one or more first integrated circuit devices (e.g., integrated circuit devices 116, integrated circuit devices 118) in a first device region (e.g., a portion of a device region 138) of a first semiconductor layer (e.g., a semiconductor layer 108, a semiconductor layer 112) of a first semiconductor die (e.g., a semiconductor die 102, a semiconductor die 104), as described herein.

As further shown in FIG. 12, process 1200 may include forming a first interconnect layer, above the first semiconductor layer, to include a first seal ring portion (block 1220). For example, one or more semiconductor processing tools may be used to form a first interconnect layer (e.g., an interconnect layer 110, an interconnect layer 114), above the first semiconductor layer, to include a first seal ring portion (e.g., a first portion of a seal ring region 140), as described herein.

As further shown in FIG. 12, process 1200 may include forming one or more second integrated circuit devices in a second device region of a second semiconductor layer of a second semiconductor die (block 1230). For example, one or more semiconductor processing tools may be used to form one or more second integrated circuit devices (e.g., integrated circuit devices 116, integrated circuit devices 118) in a second device region (e.g., a second portion of a device region 138) of a second semiconductor layer (e.g., a semiconductor layer 108, a semiconductor layer 112) of a second semiconductor die (e.g., a semiconductor die 102, a semiconductor die 104), as described herein.

As further shown in FIG. 12, process 1200 may include forming a second interconnect layer, above the second semiconductor layer, to include a second seal ring portion (block 1240). For example, one or more semiconductor processing tools may be used to form a second interconnect layer (e.g., an interconnect layer 110, and interconnect layer 114), above the second semiconductor layer, to include a second seal ring portion (e.g., a second portion of a seal ring region 140), as described herein.

As further shown in FIG. 12, process 1200 may include bonding the first interconnect layer and the second interconnect layer to form a semiconductor package (block 1250). For example, one or more semiconductor processing tools may be used to bond the first interconnect layer and the second interconnect layer to form a semiconductor package (e.g., a semiconductor package 100, a semiconductor package 600, a semiconductor package 800, a semiconductor package 900, a semiconductor package 1000, a semiconductor package 1100), as described herein. In some implementations, the first seal ring portion and the second seal ring portion are bonded together to form a seal ring region (e.g., a seal ring region 140) of the semiconductor package.

As further shown in FIG. 12, process 1200 may include forming, in the seal ring region, a through-substrate isolation structure that extends through the first semiconductor layer of the first semiconductor die (block 1260). For example, one or more semiconductor processing tools may be used to form, in the seal ring region, a through-substrate isolation structure (e.g., a through-substrate isolation structure 142, a through-substrate isolation structure 142a, a through-substrate isolation structure 142b) that extends through the first semiconductor layer of the first semiconductor die, as described herein.

Process 1200 may include additional implementations, such as any single implementation or any combination of implementations described below and/or in connection with one or more other processes described elsewhere herein.

In a first implementation, forming the first interconnect layer includes forming the first interconnect layer above a first side of the first semiconductor layer, forming the through-substrate isolation structure includes forming the through-substrate isolation structure from a second side of the first semiconductor layer vertically opposing the first side, and process 1200 includes forming, over the second side of the semiconductor layer, a conductive structure (e.g., a conductive structure 606) on the through-substrate isolation structure, and forming a connection structure (e.g., a connection structure 608) on the conductive structure.

In a second implementation, alone or in combination with the first implementation, process 1200 includes bonding the connection structure of the first semiconductor die and another connection structure (e.g., a bonding pad 814) of a third semiconductor die (e.g., a semiconductor die 802).

In a third implementation, alone or in combination with one or more of the first and second implementations, forming the second interconnect layer includes forming the second interconnect layer above a first side of the second semiconductor layer, and process 1200 includes forming another through-substrate isolation structure (e.g., a through-substrate isolation structure 142, a through-substrate isolation structure 142a, a through-substrate isolation structure 142b) from a second side of the second semiconductor layer vertically opposing the first side.

In a fourth implementation, alone or in combination with one or more of the first through third implementations, bonding the first interconnect layer and the second interconnect layer includes bonding one or more first bonding pads (e.g., bonding pads 124, bonding pads 132) in the first seal ring portion of the first interconnect layer with one or more second bonding pads (e.g., bonding pads 124, bonding pads 132) in the second seal ring portion of the second interconnect layer, where the one or more first bonding pads are coupled to one or more first conductive structures (e.g., conductive structures 122, conductive structures 130) in the first seal ring portion of the first interconnect layer by one or more first bonding vias (e.g., bonding vias 126, bonding vias 134) in the first seal ring portion of the first interconnect layer, and where the one or more second bonding pads are coupled to one or more second conductive structures (e.g., conductive structures 122, conductive structures 130) in the second seal ring portion of the second interconnect layer by one or more second bonding vias (e.g., bonding vias 126, bonding vias 134) in the second seal ring portion of the second interconnect layer.

In a fifth implementation, alone or in combination with one or more of the first through fourth implementations, process 1200 includes forming, in the first device region, another through-substrate isolation structure (e.g., another through-substrate isolation structure 142, a through-substrate isolation structure 142a, a through-substrate isolation structure 142b) that extends through the first semiconductor layer of the first semiconductor die.

Although FIG. 12 shows example blocks of process 1200, in some implementations, process 1200 includes additional blocks, fewer blocks, different blocks, or differently arranged blocks than those depicted in FIG. 12. Additionally, or alternatively, two or more of the blocks of process 1200 may be performed in parallel.

In this way, a semiconductor package includes a first semiconductor die and a second semiconductor die bonded together such that the first semiconductor die and the second semiconductor die are stacked or vertically arranged in the semiconductor package. A seal ring region is provided around the device regions of the first semiconductor die and the second semiconductor die. To prevent, minimize, and/or reduce the likelihood of electrical leakage propagating between the first and second semiconductor dies through the seal ring region, one or more through-substrate isolation structures are included through a substrate of the first semiconductor die and/or through a substrate of the second semiconductor die in the seal ring region. The through-substrate isolation structure(s) effectively extend the interconnected metallization layers in the seal ring region through the substrate of the first semiconductor die and/or through the substrate of the second semiconductor die, to thereby prevent, minimize, and/or reduce the likelihood of electrical leakage being introduced into the device region of the first semiconductor die and/or into the device region of the second semiconductor die through the substrate of the first semiconductor die and/or through the substrate of the second semiconductor die. The through-substrate isolation structure(s) may include through-silicon via(s) (TSV(s)), through-substrate trenches, and/or another type of isolation structure(s) that extend fully through the substrate of the first semiconductor die and/or through the substrate of the second semiconductor die.

As described in greater detail above, some implementations described herein provide a semiconductor package. The semiconductor package includes a first semiconductor die. The first semiconductor die includes a first semiconductor layer, a first interconnect layer vertically adjacent to the first semiconductor layer, and a first device region that includes one or more first integrated circuit devices in the first semiconductor layer. The semiconductor package includes a second semiconductor die. The second semiconductor die includes a second semiconductor layer, a second interconnect layer, vertically adjacent to the second semiconductor layer, and a second device region that includes one or more second integrated circuit devices in the second semiconductor layer. The semiconductor package includes a seal ring region laterally surrounding the first device region and the second device region. The seal ring region includes a first plurality of conductive structures in the first interconnect layer, a second plurality of conductive structures in the second interconnect layer, and a through-substrate isolation structure extending through the first semiconductor layer and physically coupled with a conductive structure of the first plurality of conductive structures.

As described in greater detail above, some implementations described herein provide a semiconductor package. The semiconductor package includes a first semiconductor die. The first semiconductor die includes a first semiconductor layer, a first interconnect layer vertically adjacent to the first semiconductor layer, and a first device region that includes one or more first integrated circuit devices in the first semiconductor layer. The semiconductor package includes a second semiconductor die. The second semiconductor die includes a second semiconductor layer, a second interconnect layer, vertically adjacent to the second semiconductor layer, and a second device region that includes one or more second integrated circuit devices in the second semiconductor layer. The semiconductor package includes a third semiconductor die. The third semiconductor die includes a third semiconductor layer and a third interconnect layer vertically adjacent to the third semiconductor layer. The third semiconductor layer includes one or more third integrated circuit devices in the third semiconductor layer. The semiconductor package includes a seal ring region laterally surrounding the first device region, the second device region, and the third device region. The seal ring region includes a first plurality of conductive structures in the first interconnect layer, a second plurality of conductive structures in the second interconnect layer, a third plurality of conductive structures in the third interconnect layer. The seal ring region further includes a first through-substrate isolation structure extending through the first semiconductor layer and physically coupled with a first conductive structure of the first plurality of conductive structures, and a second through-substrate isolation structure extending through the second semiconductor layer and physically coupled with a second conductive structure of the second plurality of conductive structures.

As described in greater detail above, some implementations described herein provide a method. The method includes forming one or more first integrated circuit devices in a first device region of a first semiconductor layer of a first semiconductor die. The method includes forming a first interconnect layer, above the first semiconductor layer, to include a first seal ring portion. The method includes forming one or more second integrated circuit devices in a second device region of a second semiconductor layer of a second semiconductor die. The method includes forming a second interconnect layer, above the second semiconductor layer, to include a second seal ring portion. The method includes bonding the first interconnect layer and the second interconnect layer to form a semiconductor package, where the first seal ring portion and the second seal ring portion are bonded together to form a seal ring region of the semiconductor package. The method includes forming, in the seal ring region, a through-substrate isolation structure that extends through the first semiconductor layer of the first semiconductor die.

The terms “approximately” and “substantially” can indicate a value of a given quantity that varies within 5% of the value (e.g., +1%, +2%, +3%, +4%, +5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first semiconductor die, comprising:
a first semiconductor layer;
a first interconnect layer vertically adjacent to the first semiconductor layer; and
a first device region comprising one or more first integrated circuit devices in the first semiconductor layer;
a second semiconductor die, comprising:
a second semiconductor layer;
a second interconnect layer vertically adjacent to the second semiconductor layer; and
a second device region comprising one or more second integrated circuit devices in the second semiconductor layer; and
a seal ring region laterally surrounding the first device region and the second device region, comprising:
a first plurality of conductive structures in the first interconnect layer;
a second plurality of conductive structures in the second interconnect layer; and
a through-substrate isolation structure extending through the first semiconductor layer and physically coupled with a conductive structure of the first plurality of conductive structures.

2. The semiconductor package of claim 1, wherein the through-substrate isolation structure comprises a closed-loop through-substrate trench extending around the first device region.

3. The semiconductor package of claim 2, wherein the closed-loop through-substrate trench comprises an aluminum copper (AlCu) structure.

4. The semiconductor package of claim 1, wherein the through-substrate isolation structure comprises a plurality of non-contiguous through-substrate trenches extending around the first device region.

5. The semiconductor package of claim 1, wherein the through-substrate isolation structure comprises:
a first closed-loop through-substrate trench extending around the first device region; and
a second closed-loop through-substrate trench extending around the first closed-loop through-substrate trench.

6. The semiconductor package of claim 1, wherein the through-substrate isolation structure comprises a copper through-substrate via (TSV) structure.

7. The semiconductor package of claim 1, wherein the through-substrate isolation structure comprises a plurality of through-substrate via (TSV) structures around the first device region.

8. The semiconductor package of claim 1, wherein the seal ring region further comprises:
one or more first bonding vias coupled with the first plurality of conductive structures;
one or more second bonding vias coupled with the second plurality of conductive structures;
one or more first bonding pads coupled with the one or more first bonding vias; and
one or more second bonding pads coupled with the one or more second bonding vias,
wherein the one or more first bonding pads are bonded with the one or more second bonding pads.

9. A semiconductor package, comprising:
a first semiconductor die, comprising:
a first semiconductor layer;
a first interconnect layer vertically adjacent to the first semiconductor layer; and
a first device region comprising one or more first integrated circuit devices in the first semiconductor layer;
a second semiconductor die, comprising:
a second semiconductor layer;
a second interconnect layer vertically adjacent to the second semiconductor layer; and
a second device region comprising one or more second integrated circuit devices in the second semiconductor layer;
a third semiconductor die, comprising:
a third semiconductor layer;
a third interconnect layer vertically adjacent to the third semiconductor layer; and
a third device region comprising one or more third integrated circuit devices in the third semiconductor layer; and
a seal ring region laterally surrounding the first device region, the second device region, and the third device region, comprising:
a first plurality of conductive structures in the first interconnect layer;
a second plurality of conductive structures in the second interconnect layer;
a third plurality of conductive structures in the third interconnect layer;
a first through-substrate isolation structure extending through the first semiconductor layer and physically coupled with a first conductive structure of the first plurality of conductive structures; and
a second through-substrate isolation structure extending through the second semiconductor layer and physically coupled with a second conductive structure of the second plurality of conductive structures.

10. The semiconductor package of claim 9, wherein the first interconnect layer is facing the second interconnect layer; and
wherein the seal ring region further comprises:
one or more first bonding vias coupled with the first plurality of conductive structures;
one or more second bonding vias coupled with the second plurality of conductive structures;
one or more first bonding pads coupled with the one or more first bonding vias; and
one or more second bonding pads coupled with the one or more second bonding vias,
wherein the one or more first bonding pads are bonded with the one or more second bonding pads.

11. The semiconductor package of claim 10, wherein the seal ring region further comprises:
one or more third bonding pads in a fourth interconnect layer on a side of the first semiconductor layer opposing a side on which the first interconnect layer is located,
wherein the one or more third bonding pads are coupled with the first through-substrate isolation structure; and
one or more fourth bonding pads in the third interconnect layer,
wherein the one or more third bonding pads are bonded with the one or more fourth bonding pads.

12. The semiconductor package of claim 9, wherein the first through-substrate isolation structure comprises copper (Cu); and
wherein the second through-substrate isolation structure comprises aluminum copper (AlCu).

13. The semiconductor package of claim 9, wherein the first device region comprises a pixel sensor array that includes plurality of pixel sensors.

14. The semiconductor package of claim 13, wherein the seal ring region is laterally adjacent to a bonding pad region; and
wherein the bonding pad region is between the seal ring region and the pixel sensor array.

15. A method, comprising:
forming one or more first integrated circuit devices in a first device region of a first semiconductor layer of a first semiconductor die;
forming a first interconnect layer, above the first semiconductor layer, to include a first seal ring portion;
forming one or more second integrated circuit devices in a second device region of a second semiconductor layer of a second semiconductor die;
forming a second interconnect layer, above the second semiconductor layer, to include a second seal ring portion;
bonding the first interconnect layer and the second interconnect layer to form a semiconductor package,
wherein the first seal ring portion and the second seal ring portion are bonded together to form a seal ring region of the semiconductor package; and
forming, in the seal ring region, a through-substrate isolation structure that extends through the first semiconductor layer of the first semiconductor die.

16. The method of claim 15, wherein forming the first interconnect layer comprises:
forming the first interconnect layer above a first side of the first semiconductor layer;
wherein forming the through-substrate isolation structure comprises:
forming the through-substrate isolation structure from a second side of the first semiconductor layer vertically opposing the first side; and
wherein the method further comprises:
forming, over the second side of the first semiconductor layer, a conductive structure on the through-substrate isolation structure; and
forming a connection structure on the conductive structure.

17. The method of claim 16, further comprising:
bonding the connection structure of the first semiconductor die and another connection structure of a third semiconductor die.

18. The method of claim 15, wherein forming the second interconnect layer comprises:
forming the second interconnect layer above a first side of the second semiconductor layer; and
wherein the method further comprises:
forming another through-substrate isolation structure from a second side of the second semiconductor layer vertically opposing the first side.

19. The method of claim 15, wherein bonding the first interconnect layer and the second interconnect layer comprises:
bonding one or more first bonding pads in the first seal ring portion of the first interconnect layer with one or more second bonding pads in the second seal ring portion of the second interconnect layer,
wherein the one or more first bonding pads are coupled to one or more first conductive structures in the first seal ring portion of the first interconnect layer by one or more first bonding vias in the first seal ring portion of the first interconnect layer, and
wherein the one or more second bonding pads are coupled to one or more second conductive structures in the second seal ring portion of the second interconnect layer by one or more second bonding vias in the second seal ring portion of the second interconnect layer.

20. The method of claim 15, further comprising:
forming, in the first device region, another through-substrate isolation structure that extends through the first semiconductor layer of the first semiconductor die.
